(19) United States
(12) Patent Application Publication
(10) Pub. No.: US 2023/0099634 A1
(43) Pub. Date: Mar. 30, 2023

(54) STYRENE-BASED RESIN COMPOSITION, FLAME RETARDANT STYRENE-BASED RESIN COMPOSITION, MOLDED BODY, AND PATCH ANTENNA

(71) Applicant: PS JAPAN CORPORATION, Bunkyo-ku, Tokyo (JP)

(72) Inventor: Akio NODERA, Chiyoda-ku, Tokyo (JP)

(73) Assignee: PS JAPAN CORPORATION, Bunkyo-ku, Tokyo (JP)

(21) Appl. No.: 17/904,594

(22) PCT Filed: Feb. 19, 2021
(86) PCT No.: PCT/JP2021/006467

§ 371 Date: Aug. 19, 2022

(30) Foreign Application Priority Data
Feb. 21, 2020 (JP) 2020-028494
Apr. 14, 2020 (JP) 2020-072534
Dec. 21, 2020 (JP) 2020-211849

(51) Int. Cl. C08L 25/14; C08L 9/06

(52) U.S. Cl. CPC C08L 25/14; C08L 9/06

(57) ABSTRACT

It would be helpful to provide a styrene-based resin molded body that has excellent dielectric constant, dielectric loss tangent, and color tone, and with little degradation in properties due to usage environment. The present disclosure is a styrene-based resin composition containing a styrene-based resin (A1) having styrene-based monomer units as repeating units. The styrene-based resin composition includes 6 μg or less of a catechol derivative contained in the styrene-based resin (A1) per gram of the styrene-based resin (A1), and the total amount of dimers of the styrene-based monomer units and trimers of the styrene-based monomer units contained in the styrene-based resin (A1) is 5000 μg or less per gram of the styrene-based resin (A1). The styrene-based resin composition has a dielectric constant of 3 or less and a dielectric loss tangent of 0.02 or less.

### TECHNICAL FIELD

The present disclosure relates to a styrene-based resin composition, a flame retardant styrene-based resin composition, a molded body, and a patch antenna.

### BACKGROUND

In electronic devices such as communication devices including cell phones, smartphones, mobile information terminals, and Wi-Fi devices, surface acoustic wave (SAW) devices, radar components, or antenna components, signal frequencies are increased to higher frequencies (0.3 GHz or higher) in order to increase communication capacity, increase communication speed, or the like. To ensure the quality, strength, or the like of high-frequency signals, components used in such high-frequency electronic devices are required to reduce transmission loss based on dielectric loss or conductor loss.

For example, JP2002-249531A (PTL 1) proposes to use a polymer material such as fluoroplastic, curable polyolefin, cyanate ester resin, curable polyphenylene oxide, allyl-modified polyphenylene ether, or polyetherimide modified with divinylbenzene or divinylnaphthalene, as components used in electronic equipment for high-frequency applications. PTL 1 discloses that by using bis(vinylphenyl)ethane as a cross-linking component having multiple styrene groups, the volatility and cured product brittleness of divinylbenzene, which is conventionally used as a cross-linking agent, are improved. In general, styrene-based resin has excellent electrical properties such as insulation and dielectric properties as well as moldability and dimensional stability, and styrene-based resin compositions with flame retardant properties are used in a wide range of applications, including home appliances and office automation equipment.

In addition, WO2018/051793 (PTL 2) discloses a glass patch antenna support in which a specific alkali metal oxide is blended, as a patch antenna support for high-frequency applications. In general, styrene-based resin has excellent electrical properties such as insulation and dielectric properties as well as moldability and dimensional stability, and styrene-based resin compositions with flame retardant properties are used in a wide range of applications, including home appliances and office automation equipment. Furthermore, JP2008-537964A (PTL 3) discloses a technology of using PTFE, which is a typical example of a dielectric substrate, as a dielectric layer.

In general, styrene-based resin is used in a wide range of applications because of excellent moldability, dimensional stability, and impact resistance. In particular, polystyrene-based resin compositions with flame retardant properties are used in a wide range of applications, including home appliances and office automation equipment, and are used for exterior parts, transparent parts, and other components that require design. However, due to recent movement to restrict halogen-containing organic compounds, especially in Europe, there is a growing demand for flame retardant resin or flame retardant resin compositions that does/do not contain bromine, which is inexpensive and has excellent balance of physical properties. For example, JP2001-192565A (PTL 4) discloses a technology to improve flame retardance by adding a phosphinic acid compound to polystyrene. Also, JP2019-183084A (PTL 5) discloses a technology for blending a phosphorus-based flame retardant and an NOR-type hindered amine compound in polystyrene-based resin.

### CITATION LIST

### Patent Literature

PTL 1: JP2002-249531A

PTL 2: WO2018/051793

PTL 3: JP2008-537964A

PTL 4: JP2001-192565A

PTL 5: JP2019-183084A

### SUMMARY

### Technical Problem

The resin disclosed in the above PTL 1 is so-called heat-resistant engineering plastic, which is curable resin that remains problematic in terms of processability or recyclability. Therefore, the shapes of molded bodies that can be processed are limited. Furthermore, since many dimers and trimers of styrene-based monomer units remain in the curable resin, a problem of increased transmission loss remains when the resin is used in high-frequency applications. In addition, as mentioned above, although it is effective for high-frequency applications to reduce transmission loss, when the polymer material such as styrene-based resin is used for high-frequency applications, usage environment changes (for example, to high-temperature environment) due to such use, and further continued use may result in new problems such as a higher dielectric constant or dielectric loss tangent, or yellowing of the material. In addition, in a case in which the styrene-based resin is used for high-frequency applications, there is a problem that the values of dielectric properties (dielectric constant and/or dielectric loss tangent) become even higher when a flame retardant is added for the purpose of providing flame retardance.

The patch antenna support disclosed in the above PTL 2 is excellent as glass, but has higher relative dielectric constant and dielectric loss tangent than polystyrene-based resin, resulting in a problem of high transmission loss. Moreover, a dielectric itself is made of glass and hence easily damaged, and the shape of a patch antenna has less flexibility. In addition, in PTL 3, Teflon resin such as PTFE used as the dielectric layer has lower dielectric loss than glass, but has less adhesion properties to a patch substrate or ground substrate (hereinafter referred to as “substrate”), which causes a new problem that these substrates peel off from the Teflon resin.

When resin is used as a dielectric, as in the case of PTL 3, yellowing is likely to occur due to oxidative degradation of the resin depending on usage environment. Such yellowing of the resin not only deteriorates a dielectric loss tangent, but also may cause a defect in product appearance, material recycling, or the like when a patch antenna is used externally (especially for transparent applications).

In the above PTL 4, the phosphinic acid compound is added to polystyrene to produce flame retardant properties. However, the phosphine compound has poor thermal stability, thus causing gas generation during molding and reducing molded appearance of a molded product, and also causing a problem with continuous molding due to adhesion to molds of molding machines. In addition, the phosphinic acid compound sublimates and is lost at processing temperature, resulting in variations in flame retardant effects. In addition, PTL 5 causes a yellowing defect phenomenon when molded, which is a problem for use in light-colored or transparent materials.

It would be helpful to provide a styrene-based resin composition and a molded body thereof that are inexpensive, have few restrictions on the shape of a product, retain excellent dielectric properties of styrene-based resin, exhibit the dielectric properties even in usage environment under high temperature conditions, and have little yellowing.

It would be also helpful to provide a patch antenna with excellent adhesion to substrates, impact resistance, dielectric constant or dielectric loss tangent, and color tone, and with little degradation in properties due to usage environment.

It would be also helpful to provide a flame retardant styrene-based resin composition that stably exhibits high flame retardance and have excellent color tone, excellent molded appearance, and high heat resistance, and a molded product containing the styrene-based resin composition.

### Solution to Problem

The inventor has made a diligent study to solve the above problems, and found that when a styrene-based resin (A1) contains a catechol derivative by a specific amount or less, and dimers and trimers of styrene-based monomer units, which are component units of a styrene-based resin (A1), by a specific amount or less, the dielectric properties of the styrene-based resin (A1) have a dielectric constant of 3 or less and a dielectric loss tangent of 0.02 or less, and therefore a styrene-based resin composition and a molded body using the styrene-based resin composition that exhibit these dielectric properties and have little yellowing, even when used for a long period of time under high temperature conditions, are provided, which has led to completion of the present disclosure.

As another aspect of the present disclosure, it is found that by using a styrene-based resin composition having a specific composition as a dielectric layer, a patch antenna that retains excellent dielectric properties of a styrene-based resin, restricts degradation in those dielectric properties even after long-term use under high temperature conditions, has little yellowing, and has excellent adhesion to substrates can be provided.

As another aspect of the present disclosure, it is found that by adding a phosphinic acid compound and an NOR-type hindered amine compound in a specific ratio to a styrene-based resin, a flame retardant styrene-based resin composition that stably exhibits high flame retardance (that is, reduced variations in flame retardance effects) and has excellent color tone, excellent molded appearance, and high heat resistance can be obtained.

In other words, the present disclosure is as follows:

[1] The present disclosure is a styrene-based resin composition containing a styrene-based resin (A1) having styrene-based monomer units as repeating units, the styrene-based resin composition including:

6 μg or less of a catechol derivative contained in the styrene-based resin (A1) per gram of the styrene-based resin (A1), and the total amount of dimers of the styrene-based monomer units and trimers of the styrene-based monomer units contained in the styrene-based resin (A1) being 5000 μg or less per gram of the styrene-based resin (A1),

wherein the styrene-based resin composition has a dielectric constant of 3 or less and a dielectric loss tangent of 0.02 or less.

[2] In the present disclosure, the styrene-based resin (A1) is preferably a rubber-modified styrene-based resin in which particles of a rubbery polymer (a) are dispersed in a polymer matrix having monovinylstyrene-based monomer units as repeating units, or a styrene copolymer resin containing the styrene-based monomer units and unsaturated carboxylic acid monomer units and/or unsaturated carboxylic acid ester monomer units.
[3] In the present disclosure, the styrene-based resin composition further preferably includes a flame retardant (B).
[4] In the present disclosure, the flame retardant (B) is preferably one or two or more selected from the group consisting of phosphorus-based flame retardants, bromine-based flame retardants, and hindered amine compounds (C2).
[5] In the present disclosure, the styrene-based resin composition further preferably includes:

77.0 mass % to 98.8 mass % of the styrene-based resin (A2); and

1.0 mass % to 20.0 mass % of a phosphinic acid compound (C1) and 0.2 mass % to 3.0 mass % of a hindered amine compound (C2), as the flame retardant (B).

[6] In the present disclosure, the styrene-based resin (A1) is preferably a thermoplastic styrene-based resin (b).
[7] The present disclosure is a styrene-based resin molded body with the styrene-based resin composition according to any one of the above [1] to [6],

wherein the styrene-based resin molded body is for a component of an apparatus communicating by an electromagnetic wave with a frequency of 0.3 GHz to 300 GHz, or for a housing or a housing component.

[8] In the present disclosure, the styrene-based resin molded body is preferably at least one selected from the group consisting of transmitters and receivers, cellular phones, tablets, laptops, navigation devices, surveillance cameras, photographic cameras, sensors, diving computers, audio units, remote controls, speakers, headphones, radios, televisions, lighting equipment, household appliances, kitchen appliances, door openers or gate openers, operating devices for vehicle central locking, keys for keyless cars, temperature measurement or temperature display devices, components of measurement and control devices, and housings or housing components.
[9] The present disclosure is a patch antenna including:

a patch substrate;

a ground substrate provided at a distance from the patch substrate; and

a dielectric layer sandwiched between the patch substrate and the ground substrate,

wherein

the dielectric layer is composed of a styrene-based resin composition containing a catechol derivative, a styrene-based resin (A1) having styrene-based monomer units as repeating units, dimers of the styrene-based monomer units, and trimers of the styrene-based monomer units,

the catechol derivative is 6 μg or less per gram of the styrene-based resin (A1), and

the total amount of the dimers of the styrene-based monomer units and the trimers of the styrene-based monomer units is 5000 μg or less per gram of the styrene-based resin (A1).

[10] In the present disclosure, the flame retardant (B) is preferably contained by 1 mass % to 30 mass % relative to the total amount (100 mass %) of the styrene-based resin composition.
[11] In the present disclosure, the phosphorus-based flame retardant is preferably a phosphate ester compound esterified with alkylphenol, or a phosphine compound.
[12] In the present disclosure, the bromine-based flame retardant is preferably at least one selected from the group consisting of brominated diphenylalkanes, brominated phthalimides, and tris(polybromophenoxy)triazine compounds.
[13] In the present disclosure, the dielectric layer further preferably contains a flame retardant (B).
[14] In the present disclosure, the patch substrate is preferably electrically connected to a coaxial line via a power supply point.
[15] In the present disclosure, the patch substrate is preferably hexagonal in shape.
[16] In the present disclosure, a microarray type in which a plurality of the patch substrates are arranged is preferably adopted.
[17] The present disclosure is a frame-retardant styrene-based resin composition including:

77.0 mass % to 98.8 mass % of a styrene-based resin (A2); and

1.0 mass % to 20.0 mass % of a phosphinic acid compound (C1) and a 0.2 mass % to 3.0 mass % of a hindered amine compound (C2), as a flame retardant (B).

[18] In the present disclosure, the hindered amine compound (C2) is preferably an NOR-type hindered amine compound.
[19] In the present disclosure, the phosphinic acid compound (C1) is preferably 9,10-dihydro-9-oxa-10-phosphaphenanthrene-10-oxide.
[20] The present disclosure is a molded product with the frame-retardant styrene-based resin composition described in any of the above [17] to [19].

### Advantageous Effects

According to the present disclosure, it is possible to provide a styrene-based resin composition and a molded body thereof with an excellent dielectric constant or dielectric loss tangent and excellent color tone, and with little decrease in dielectric properties depending on change in usage environment.

According to the present disclosure, it is possible to provide a patch antenna with excellent adhesion to substrates, dielectric constant or dielectric loss tangent, impact resistance, and color tone, and with little degradation in properties depending on usage environment.

According to the present invention, it is possible to provide a styrene-based resin composition that stably exhibit high flame retardance and have excellent color tone, excellent molded appearance, and high heat resistance, and a molded product containing the styrene-based resin composition.

### BRIEF DESCRIPTION OF THE DRAWINGS

In the accompanying drawings:

FIGS. 1A and 1B are schematic diagrams illustrating examples of a patch antenna according to an embodiment, FIG. 1A is the schematic diagram of the patch antenna with a microstrip line, and FIG. 1B is the schematic diagram of the patch antenna with a power supply point;

FIG. 2 is a schematic diagram of an example of microarray type patch antennas;

FIG. 3 is a schematic diagram illustrating an example of dielectric evaluation using a microstrip line method;

FIGS. 4A to 4C are images illustrating an example of a manufacturing method of samples used to evaluate minimum copper foil adhesion; and

FIG. 5 is a graph illustrating an example of results of the minimum copper foil adhesion.

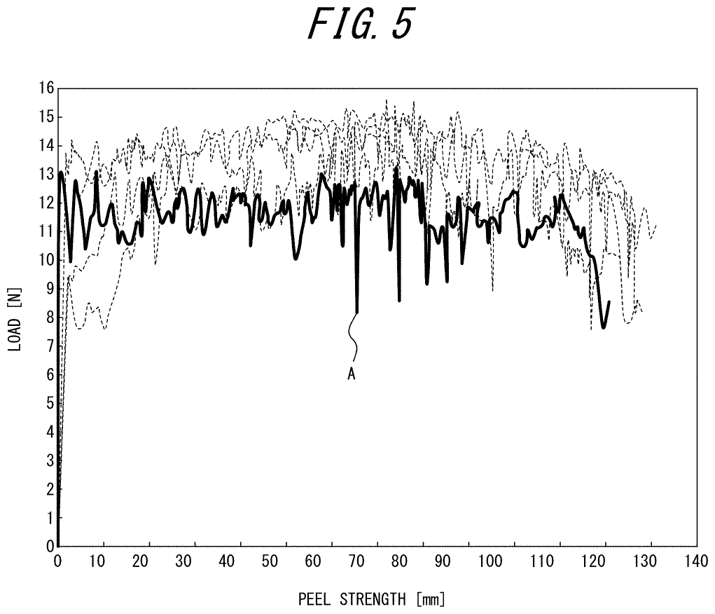

### DETAILED DESCRIPTION

An embodiment of the present disclosure (hereinafter referred to as “embodiment”) will be described below in detail, but the present disclosure is not limited to the following description and may be implemented with various modifications within the scope of its gist.

[Styrene-Based Resin Composition]

A styrene-based resin composition of the present disclosure can be broadly divided into two categories. The first styrene-based resin composition contains a styrene-based resin (A1), a catechol derivative, dimers of styrene-based monomer units, which are repeating units constituting the styrene-based resin (A1), and trimers of the styrene-based monomer units, and a flame retardant (B) to be blended as required.

The second styrene-based resin composition is a flame retardant styrene-based resin composition that contains a styrene-based resin (A2), a phosphinic acid compound (C1), and a hindered amine compound (C2). As described below, while the catechol derivative, the dimers of the styrene-based monomer units, which are the repeating units constituting the styrene-based resin (A1), and the trimers of the styrene-based monomer units are physically incorporated in the styrene-based resin (A1), the styrene-based resin (A2) includes a form in which a catechol derivative, dimers of styrene-based monomer units and trimers of the styrene-based monomer units are not physically incorporated.

The styrene-based resin composition of the present embodiment indispensably contains the styrene-based resin (A1) (hereinafter also referred to as (A1) component), and contains 6 μg or less of the catechol derivative in the styrene-based resin (A1) per gram of styrene-based resin (A1). The total amount of the dimers of the styrene-based monomer units, which are the repeating units constituting the styrene-based resin (A1), and the trimers of the styrene-based monomer units contained in the styrene-based resin (A1) is 5000 μg or less per gram of the styrene-based resin (A1). The styrene-based resin composition has a dielectric constant of 3 or less, and a dielectric loss tangent of 0.02 or less. The styrene-based resin composition may contain a flame retardant (B) if necessary. Thus, the styrene-based resin composition of the present embodiment may be used as a material with a low dielectric constant and low dielectric loss tangent.

Another aspect of the styrene-based resin composition of the present embodiment is a frame-retardant styrene-based resin composition containing 77.0 mass % to 98.8 mass % of the styrene-based resin (A2) (hereinafter also referred to as (A2) component), and 1.0 mass % to 20.0 mass % of the phosphinic acid compound (C1) (hereinafter also referred to as (C1) component), and 0.1 mass % to 3.0 mass % of the hindered amine compound (C2) (hereinafter also referred to as (C2) component). This provides the flame retardant styrene-based resin composition that has extremely improved flame retardance, that stably exhibits high flame retardant properties with reduced variations in flame retardant effects, and that has excellent color tone, excellent molded appearance, and high heat resistance.

It has been confirmed that in the styrene-based resin composition of the present disclosure, when a resin in which (the content of the catechol derivative in styrene-based resin (A1))/(1 g of the styrene-based resin (A1)) is 6 μg or less, and (the total content of the dimers of the styrene-based monomer units and the trimers of the styrene-based monomer units in the styrene-based resin (A1))/(1 g of the styrene-based resin (A1)) is 5000 μg or less is used, there is little degradation in the performance of the low dielectric constant and low dielectric loss tangent. In high-frequency applications, temperature under usage environment is high and the styrene-based resin is susceptible to yellowing and degradation, so degradation in the performance of the low dielectric constant and low dielectric loss tangent is reduced by keeping the amounts of 4-t-butylcatechol, styrene dimers, and styrene trimers in the styrene-based resin composition at predetermined levels or less.

In the present embodiment, the concentration of the catechol derivative is preferably 6 μg or less per gram of the styrene-based resin (A1), and more preferably 3 μg or less per gram of the styrene-based resin (A1). When the concentration exceeds 6 μg per gram of the styrene-based resin (A1), yellowing becomes larger during use, and the value of the dielectric loss tangent increases. The total amount of the dimers of the styrene-based monomer units and the trimers of the styrene-based monomer units is preferably 5000 μg or less per gram of the resin composition, and more preferably 3000 μg or less per gram of the resin composition. When the total amount of the styrene dimers and the styrene trimers exceeds 5000 μg per gram of the resin composition, the values of the dielectric constant and dielectric loss tangent during use become larger.

[Styrene-Based Resin (A1): (A1) Component]

In the styrene-based resin composition of the present embodiment, the content of the styrene-based resin (A1) (excluding the contents of the catechol derivative and the dimers and trimers of the styrene-based monomer units. The same meaning applies to the content of styrene-based resin (A1) below.) is preferably 70.0 mass % to 100 mass % relative to the total composition (100 mass %), more preferably 99.7 mass % to 100 mass %, and even more preferably 99.75 mass % to 100 mass %. By setting the content to 99.5 mass % or more, the effect of preventing increases in the dielectric constant and dielectric loss tangent can be improved even when the styrene-based resin is used for long time under high temperature. By setting the content to 100 mass % or less, the effects of a low dielectric constant and a low dielectric loss tangent can be achieved.

As impurities or additives of the styrene-based resin (A1), the catechol derivative, the dimers of the styrene-based monomer units, and the trimers of the styrene-based monomer units are incorporated into the styrene-based resin (A1). Thus, for example, the term “catechol derivative contained in the styrene-based resin (A1)” in the claims means that the catechol derivative is physically incorporated into the styrene-based resin (A1). Likewise, the dimers of the styrene-based monomer units and the trimers of the styrene-based monomer units are also physically incorporated into the styrene-based resin (A1). In this specification, the styrene-based resin (A1), the catechol derivative, the dimers of the styrene-based monomer units, and the trimers of the styrene-based monomer units are different from each other in chemical structure and the like, and are therefore considered separate components from each other. Therefore, in this specification, the term “the content of the styrene-based resin (A1)” includes, unless otherwise stated, neither the content of the catechol derivative incorporated in the styrene-based resin (A1) nor the content of the dimers of the styrene-based monomer units and the trimers of the styrene-based monomer units incorporated in the styrene-based resin (A1).

The styrene-based resin (A1) that can be used in the present embodiment is a resin obtained by polymerizing the styrene-based monomer units and, if necessary, one or more types of monomer units and/or polymers selected from other vinyl monomer units and rubbery polymers (a) that can be copolymerized with the styrene-based monomer units. Specifically, there are, for example, but not limited to, polystyrene, rubber-modified styrene-based resins in which particles of the rubbery polymer (a) are dispersed in a polymer matrix, and styrene copolymer resins. Therefore, the styrene-based resin (A1) of the present disclosure contains the styrene-based monomer units as an essential component and, if necessary, another/other vinyl monomer unit/units and/or rubbery polymer monomer unit/units.

In the present embodiment, the styrene-based monomer unit, which is a repeating unit constituting the styrene-based resin (A1), is preferably a monovinylstyrene-based monomer unit. In addition, the styrene-based resin (A1) contains a cross-linkable aromatic vinyl compound (unit) such as an aromatic compound (unit) having two or more vinyl groups (e.g., divinylbenzene) preferably in 4.5 mass % or less, and more preferably in 3 mass % or less. This makes it easier to reduce the total content with the dimers and trimers of the styrene-based monomer units.

The styrene-based resin (A1) that can be used in the present embodiment contains 6 μg or less of the catechol derivative per gram of the styrene-based resin (A1). In the styrene-based resin (A1), the total content of the dimers of styrene-based monomer units, which are repeating units constituting the styrene-based resin (A1), and the trimers of the styrene-based monomer units is 5000 μg or less per gram of the styrene-based resin (A1).

[Catechol Derivative]

The catechol derivative in the present embodiment is contained as an impurity or additive in the styrene-based resin (A1), and is mainly contained in a production process of the styrene-based monomer units forming the styrene-based resin (A1) or is pre-mixed as an additive to the styrene-based resin (A1). When the catechol derivative is contained in a predetermined amount (6 μg per gram of the styrene-based resin (A1)) or more, catechol becomes a quinone structure under high-temperature use, which causes the occurrence of yellowing and increase in the dielectric constant and dielectric loss tangent.

In the present embodiment, the catechol derivative is more than 0 mass % and 0.00006 mass % or less, preferably more than 0 mass % and 0.00004 mass % or less, and more preferably more than 0 mass % and 0.00003 mass % or less relative to the total styrene-based resin composition (mass %).

The catechol derivative of the present disclosure is preferably represented by the following general formula (I).

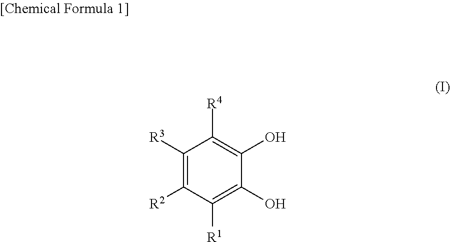

(In the above general formula (I), R¹, R², R³, and R⁴ are each independently a hydrogen atom, a linear, branched, or cyclic alkyl group with 1 to 6 carbon atoms, or an aryl group.)

As the linear, branched, or cyclic alkyl group with 1 to 6 carbon atoms, a linear or branched alkyl group with 1 to 5 carbon atoms is preferred, and a branched alkyl group with 1 to 4 carbon atoms is more preferred. Specifically, the alkyl group includes a methyl group, an ethyl group, a propyl group (including an n-propyl group and an isopropyl group), a butyl group (including an n-butyl group, a sec-butyl group, an isobutyl group, a t-butyl group, and an n-butyl group), a pentyl group (including n-pentyl, neopentyl, a sec-pentyl group, an isopentyl group, a 3-pentyl group, and a t-pentyl group), and the like.

The aryl group includes a phenyl group and a naphthyl group, and one or more hydrogen atoms of the aryl group may be replaced by the linear or branched alkyl group with 1 to 5 carbon atoms.

As the catechol derivative of the present disclosure, 4-t-butylcatechol (hereinafter abbreviated as TBC) or 3,5-di-t-butylcatechol is preferred, and 4-t-butylcatechol is particularly preferred.

In the styrene-based resin composition of the present disclosure, in particular, when the concentration of 4-t-butylcatechol is preferably 6 μg or less per gram of the styrene-based resin (A1) and more preferably 3 μg or less per gram of the styrene-based resin (A1), a variation in the dielectric loss tangent is reduced and yellowing can be prevented.

In the present embodiment, the content of the catechol derivative is measured using gas chromatography. Specifically, the following measurement conditions are used.

Instrument: Agilent 6890

Sample: After dissolving 1 g of the resin composition in 50 ml of chloroform, BSTFA (N,O-bis(trimethylsilyl)trifluoroacetamide) was used to perform trimethylsilyl derivatization treatment.

Column: DB-1 (0.25 mm I.D.×30 m)

Liquid phase thickness: 0.25 mm

Column temperature: 40° C. (hold for 5 minutes) (temperature increase at 20° C./min) 320° C. (hold for 6 minutes): 25 minutes in total

Inlet temperature: 320° C.

Injection method: Split method (split ratio 1:5)

Sample amount: 2 μl

MS instrument: Agilent MSD5973

Ion source temperature: 230° C.

Interface temperature: 320° C.

Ionization method: Electron ionization (EI) method

Measurement method: SCAN method (scan range m/Z of 10 to 800)

As a method of reducing the amount of the catechol derivative in the styrene-based resin (A1) to a predetermined level or less, there is a method in which the styrene-based resin (A1) is distillated and purified.

[Dimers and Trimers]

The dimers and trimers of the styrene-based monomer units in the present embodiment are contained as impurities in the styrene-based resin (A1), and are mainly generated when the styrene-based resin (A1) is polymerized. When the total amount of the dimers and trimers is a predetermined level (5000 μg or more per gram of the styrene-based resin (A1)) or more, oxides of the dimers and trimers have a quinone structure, thus causing yellowing and increase in the dielectric constant and dielectric loss tangent.

In the present embodiment, the dimers and trimers are more than 0 mass % and 0.5 mass % or less, preferably more than 0 mass % and 0.3 mass % or less, and more preferably more than 0 mass % and 0.25 mass % or less relative to the total styrene-based resin composition (100 mass %).

The chemical structures of the dimers and trimers of the styrene-based monomer units depend on the styrene-based monomer units contained in the styrene-based resin (A1) to be used, as described below.

In the present embodiment, the total amount of the dimers and trimers of the styrene-based monomer units is measured using gas chromatography. Specifically, the following measurement form is used.

Instrument: Agilent 6850 series GC system

Sample: After dissolving 1 g of the resin composition in 10 ml of MEK, 3 ml of methanol was added to precipitate the polymer and a component concentration in the solution was measured.

Column: Agilent 19091Z-413E

Entrance temperature: 250° C.

Detector temperature: 280° C.

As a method of reducing the amount of the dimers and trimers in the styrene-based resin (A1) to a predetermined level or less, there is a method in which the styrene-based resin (A1) is distillated and purified.

<Polystyrene>

In the present embodiment, polystyrene is a monopolymer of styrene-based monomer units, and a commonly available one can be selected and used as appropriate. The styrene-based monomer unit is preferably a monovinylstyrene-based monomer unit. This not only makes it easier to form thermoplastic polystyrene, but also reduces the amount of dimers and trimers of the styrene-based monomer units. The styrene-based monomer unit constituting polystyrene includes, in addition to styrene, α-methylstyrene, α-methyl-p-methylstyrene, o-methylstyrene, m-methyl styrene, p-methylstyrene, vinyltoluene, ethylstyrene, isobutylstyrene, and t-butyl styrene, and styrene derivatives such as bromostyrene and indene. Styrene is particularly preferred from an industrial standpoint. One or more types of these styrene-based monomer units can be used. Polystyrene typically consists of styrene-based monomer units, although it is not excluded to contain further monomer units other than the above styrene-based monomer units to the extent that the effect of the present disclosure is not impaired.

<Rubber-Modified Styrene-Based Resin>

In the present embodiment, the rubber-modified styrene-based resin is one in which particles of a rubbery polymer (a) are dispersed in a styrene-based resin as a polymer matrix, and can be produced by polymerizing styrene-based monomer units in the presence of the rubbery polymer (a). A styrene component in the polymer matrix is preferably composed of monovinylstyrene-based monomer units. This not only facilitates the formation of thermoplastic polystyrene, but also reduces the amount of dimers and trimers of the styrene-based monomer units.

The styrene-based monomer unit that constitutes the rubber-modified styrene-based resin of the present embodiment is preferably a monovinylstyrene-based monomer unit. The styrene-based monomer unit constituting rubber-modified styrene-based resin includes, in addition to styrene, α-methylstyrene, α-methyl-p-methylstyrene, o-methylstyrene, m-methylstyrene, p-methylstyrene, vinyltoluene, ethylstyrene, isobutylstyrene, and t-butylstyrene, and styrene derivatives such as bromostyrene and indene. Styrene is particularly preferred. One or more types of these styrene-based monomer units can be used.

The rubbery polymer (a) contained in the rubber-modified styrene-based resin of the present embodiment may, for example, encapsulate a resin containing styrene-based monomer units obtained from the above styrene-based monomer units on its inner side and/or be grafted with a resin containing styrene-based monomer units on its outer side.

As the rubbery polymer (a), for example, polybutadiene (including polystyrene or acrylic resin encapsulated forms), polyisoprene, natural rubber, polychloroprene, a styrene-butadiene copolymer, an acrylonitrile-butadiene copolymer, or the like can be used, but polybutadiene or the styrene-butadiene copolymer is preferred. As polybutadiene, both high-cis polybutadiene with high cis content and low-cis polybutadiene with low cis content can be used. In addition, as structure of the styrene-butadiene copolymer, both random and block structures can be used. One or more types of these rubbery polymers (a) can be used. In addition, saturated rubber hydrogenated with butadiene rubber can also be used.

Examples of such rubber-modified styrene-based resin include HIPS (high impact polystyrene), ABS resins (acrylonitrile-butadiene-styrene copolymer), AAS resins (acrylonitrile-acrylic rubber-styrene copolymer), AES resins (acrylonitrile-ethylene-propylene rubber-styrene copolymer), and the like.

When the rubber-modified styrene-based resin is HIPS resin, high-cis polybutadiene in which a cis-1,4 bond content is 90 mol % or more is particularly preferred among these rubbery polymers (a). In the high-cis polybutadiene, a vinyl-1,2 bond content is preferably 6 mol % or less, and specifically preferably 3 mol % or less.

The content of compounds having cis-1,4, trans-1,4, or vinyl-1,2 structure, as isomers related to the constituent units of the high-cis polybutadiene, can be measured using an infrared spectrophotometer and calculated by data processing using the Morello method.

The high-cis polybutadiene can be easily obtained by polymerizing 1,3-butadiene using a known production method, for example, using a catalyst containing an organic aluminum compound and a cobalt or nickel compound.

The content of the rubbery polymer (a) in the rubber-modified styrene-based resin is preferably 3 mass % to 20 mass %, and more preferably 5 mass % to 15 mass % relative to 100 mass % of the rubber-modified styrene-based resin. When the content of the rubbery polymer (a) is less than 3 mass %, the impact resistance of the styrene-based resin may decrease. When the content of the rubbery polymer (a) exceeds 20 mass %, flame retardance may decrease.

In the present disclosure, the content of the rubbery polymer (a) in the rubber-modified styrene-based resin is a value calculated using pyrolysis gas chromatography.

The average particle diameter of the rubbery polymer (a) contained in the rubber-modified styrene-based resin is preferably 0.5 μm to 4.0 μm, and more preferably 0.8 μm to 3.5 μm, in terms of impact resistance and flame retardance.

In the present disclosure, the average particle diameter of the rubbery polymer (a) contained in the rubber-modified styrene-based resin can be measured by the following method.

An ultra-thin section of 75 nm thickness is produced from the rubber-modified styrene-based resin stained with osmium tetroxide and a photograph is taken using an electron microscope at a magnification of 10000 times. In the photograph, black-stained particles are the rubbery polymer (a). From the photograph, area-averaged particle diameters are calculated, and the average particle diameter of the rubbery polymer (a) is obtained by the following formula (N1):

Average particle diameter=ΣniDri³/ΣniDri² (N1)

(In the above formula (N1), ni is the number of particles of the rubbery polymer (a) with a particle diameter Dri. The particle diameter Dri is a particle diameter calculated as a circular equivalent diameter from the area of the particle in the photograph.)
This measurement is performed by capturing the photograph into a scanner with a resolution of 200 dpi and performing measurement using particle analysis software of the image analysis device IP-1000 (Asahi Kasei Corporation).

The reduced viscosity of the rubber-modified styrene-based resin (which is an index of the molecular weight of the rubber-modified styrene-based resin) is preferably in the range of 0.50 dL/g to 0.85 dL/g, and more preferably in the range of 0.55 dL/g to 0.8 dL/g. When the reduced viscosity is smaller than 0.50 dL/g, impact strength is reduced. When the reduced viscosity exceeds 0.85 dL/g, moldability may decrease due to lower flowability.

In the present disclosure, the reduced viscosity of the rubber-modified styrene-based resin is a value measured in toluene solution at 30° C. and at a concentration of 0.5 g/dL.

A production method of the rubber-modified styrene-based resin is not particularly limited, but the rubber-modified styrene-based resin can be produced by bulk polymerization (or solution polymerization) in which styrene-based monomer units (and solvent) are polymerized in the presence of the rubbery polymer (a), bulk-suspension polymerization in which suspension polymerization is carried out during a reaction, or emulsion-graft polymerization in which styrene-based monomer units are polymerized in the presence of rubbery polymer (a) latex. In the bulk polymerization, the rubber-modified styrene-based resin can be produced by continuously feeding a mixed solution of the rubbery polymer (a) and the styrene-based monomer units, into which organic solvent, organic peroxide, and/or a chain transfer agent are/is added as needed, to a polymerization apparatus constituted of a complete mixing reactor or tank-type reactor and multiple tank-type reactors connected in series.

<Styrene Copolymer Resin>

In the present embodiment, the styrene copolymer resin is a resin containing the styrene-based monomer units and other monomer units that can copolymerize with the styrene-based monomer units. One example of the other monomer units that can copolymerize with the styrene-based monomer units, for example, is a resin that contains the styrene-based monomer units as an essential component and unsaturated carboxylic acid monomer units and/or unsaturated carboxylic acid ester monomer units as an optional component. The styrene-based monomer unit is preferably composed of the monovinylstyrene-based monomer unit. This not only facilitates formation of thermoplastic polystyrene, but also reduces the amount of dimers and trimers of the styrene-based monomer units. In the styrene copolymer resin, when the total content of the styrene-based monomer units, unsaturated carboxylic acid monomer units, and unsaturated carboxylic acid ester monomer units is 100 mass %, the content of the styrene-based monomer units is preferably 69 mass % to 98 mass %, more preferably 74 mass % to 96 mass %, and even more preferably in the range of 77 mass % to 92 mass %. When the content of the styrene-based monomer units is 69 mass % or more, the flowability of the resin can be improved. On the other hand, when the content of the styrene-based monomer units is 98 mass % or less, the desired amount of the unsaturated carboxylic acid monomer units and the unsaturated carboxylic acid ester monomer units described below, which are optional components, is less likely to be present, and it becomes difficult to obtain the effects of these monomer units described below.

In the styrene copolymer resin of the present embodiment, the unsaturated carboxylic acid monomer units play a role in improving heat resistance. When the total content of the styrene-based monomer units, unsaturated carboxylic acid monomer units, and unsaturated carboxylic acid ester monomer units in the styrene copolymer resin is 100 mass %, the content of the unsaturated carboxylic acid monomer units is preferably 16 mass % or less, more preferably 0 mass % or more and 14 mass % or less, and even more preferably 5 mass % or more and 13 mass % or less. When the content exceeds 16 mass %, the dielectric constant and dielectric loss tangent become high, and dielectric loss becomes large in high-frequency applications. In particular, by setting the content of the unsaturated carboxylic acid monomer units to more than 0 mass % and 16 mass % or less, the effect of heat resistance is more easily demonstrated, and therefore it is possible to reduce the effects of heat generated under conditions unique to electronic equipment for high-frequency applications, i.e., by exposure to electromagnetic waves in the high-frequency range.

In addition, by setting the content of the unsaturated carboxylic acid monomer units to 16 mass % or less, when the styrene-based resin composition (especially, flame retardant styrene-based resin composition) of the present embodiment is used as a master batch, excellent dispersibility with styrene-based resins can be demonstrated, which improves molded appearance, resin flowability, and mechanical properties, as well as improves flame retardance.

In general, styrene-methacrylic acid resins, including styrene-methacrylic acid-methyl methacrylate copolymer resins, are almost always produced by radical polymerization on an industrial scale. In the present embodiment, polymerization can be performed with addition of various alcohols to a polymerization system to reduce a gelation reaction in a devolatilization process.

The unsaturated carboxylic acid ester monomer units can be used to reduce a dehydration reaction of the unsaturated carboxylic acid monomer units through intermolecular interaction with the unsaturated carboxylic acid monomer units, and to improve the mechanical strength of the resin. Furthermore, the unsaturated carboxylic acid ester monomer units also contribute to improving resin properties such as weather resistance and surface hardness.

In the present embodiment, when the total content of the styrene-based monomer units, unsaturated carboxylic acid monomer units, and unsaturated carboxylic acid ester monomer units is 100 mass %, the content of the unsaturated carboxylic acid ester monomer units is preferably 0 mass % to 15 mass %, more preferably 1 mass % to 12 mass %, and even more preferably 2 mass % to 10 mass %. When the content is 15 mass % or less, the flowability of the resin can be improved and water absorption can be reduced. In addition, by setting the content of the unsaturated carboxylic acid ester monomer units to 0 mass %, heat resistance can be improved, and costs can be reduced, but from the above viewpoint, the content of the unsaturated carboxylic acid ester monomer units can be set to more than 0 mass %. In particular, by setting the content of the unsaturated carboxylic acid ester monomer units to more than 0 mass % and 15 mass % or less, the high flowability and low water absorption of the resin can be maintained, making it ideal for materials used in precision electronic devices.

When the unsaturated carboxylic acid monomer unit and the unsaturated carboxylic acid ester monomer unit are bonded next to each other, if a high temperature, high vacuum devolatilizer is used, depending on conditions, a de-alcoholization reaction may occur and a six-membered ring anhydride may be formed. The copolymer resin of the present embodiment may contain this six-membered ring anhydride, but less six-membered ring anhydride produced is preferred because the six-membered ring anhydride reduces flowability.

In the present embodiment, the content of the styrene-based monomer units (e.g., styrene monomer units), the unsaturated carboxylic acid monomer units (e.g., methacrylic acid monomer units), and the unsaturated carboxylic acid ester monomer units (e.g., methyl methacrylate monomer units) in the styrene copolymer resin can each be determined from the integral ratio of spectra measured on a proton nuclear magnetic resonance (¹H-NMR) measuring machine.

In the present embodiment, the styrene copolymer resin does not exclude further inclusion of monomer units other than the styrene-based monomer units and the unsaturated carboxylic acid monomer units and unsaturated carboxylic acid ester monomer units, which are optional components, to the extent that the effect of the present disclosure is not impaired. However, the styrene copolymer resin in the present disclosure typically should be constituted of the styrene-based monomer units, the unsaturated carboxylic acid monomer units, and the unsaturated carboxylic acid ester monomer units.

The styrene-based monomer unit that composes the styrene copolymer resin of the present embodiment is not particularly limited, but includes styrene, α-methylstyrene, α-methyl-p-methylstyrene, o-methylstyrene, m-methyl styrene, p-methylstyrene, vinyltoluene, ethylstyrene, isobutylstyrene, and t-butyl styrene, and styrene derivatives such as bromostyrene and indene. As the styrene-based monomer unit, styrene is preferred from an industrial standpoint. One type of the styrene-based monomer unit can be used alone, or two or more types can be used in combination.

The unsaturated carboxylic acid monomer unit constituting the styrene copolymer resin of the present embodiment is not particularly limited, but includes methacrylic acid, acrylic acid, maleic anhydride, maleic acid, fumaric acid, itaconic acid, and the like. As the unsaturated carboxylic acid monomer unit, methacrylic acid is preferred because the methacrylic acid is highly effective in improving heat resistance, is liquid at room temperature, and has excellent handling properties. One type of the unsaturated carboxylic acid monomer unit can be used alone, or two or more types can be used in combination.

The unsaturated carboxylic acid ester monomer unit constituting the copolymer resin of the present embodiment is not particularly limited, but includes methyl (meth)acrylate, ethyl (meth)acrylate, propyl (meth)acrylate, butyl (meth)acrylate, cyclohexyl (meth)acrylate, and the like. Methyl (meth)acrylate is preferred as a (meth)acrylic ester monomer unit because of its low effect on degradation in heat resistance. One type of the unsaturated carboxylic acid ester monomer unit can be used alone, or two or more types can be used in combination.

A suitable styrene copolymer resin of the present embodiment includes a styrene-methacrylic acid copolymer, styrene-methyl methacrylate copolymer, styrene-methacrylic acid-methyl methacrylate copolymer, styrene-acrylic acid copolymer, styrene-methyl acrylate copolymer, styrene-acrylic acid-methyl acrylate copolymer, styrene-methyl methacrylate-butyl methacrylate copolymer, styrene-butyl methacrylate copolymer, styrene-maleic anhydride copolymer, and the like.

In the present embodiment, the weight average molecular weight (Mw) of the styrene copolymer resin is preferably 100,000 to 350,000, more preferably 120,000 to 300,000, and even more preferably 140,000 to 240,000. When the weight average molecular weight (Mw) is 100,000 to 350,000, a resin with a better balance between mechanical strength and flowability can be obtained, and there is less gel contamination. The weight average molecular weight (Mw) is a value obtained by gel permeation chromatography in terms of polystyrene.

In the present embodiment, a polymerization method of the styrene copolymer resin is not particularly limited, but for example, a bulk polymerization method or solution polymerization method can be suitably employed as a radical polymerization method. The polymerization method mainly includes a polymerization process in which a polymerization raw material (monomer component) is polymerized, and a devolatilization process in which a volatile component such as unreacted monomers and a polymerization solvent are removed from a polymerization product.

An example of the polymerization method of the styrene copolymer resin that can be used in the present embodiment will be described below.

When a polymerizing raw material is polymerized to obtain the styrene copolymer resin, a polymerization initiator and a chain transfer agent are typically contained in a polymerization raw material composition.

The polymerization initiator to be used in polymerization of the styrene copolymer resin includes organic peroxides including, for example, peroxyketals such as 2,2-bis(t-butylperoxy)butane, 1,1-bis(t-butylperoxy)cyclohexane, and n-butyl-4,4-bis(t-butylperoxy)valerate, dialkyl peroxides such as di-t-butylperoxide, t-butylcumylperoxide, and dicumylperoxide, diacyl peroxides such as acetyl peroxide and isobutyryl peroxide, peroxydicarbonates such as diisopropyl peroxydicarbonate, peroxyesters such as t-butylperoxyacetate, ketone peroxides such as acetylacetone peroxide, hydroperoxides such as t-butyl hydroperoxide, and the like. From the viewpoint of decomposition speed and polymerization speed, 1,1-bis(t-butylperoxy)cyclohexane is preferred.

The chain transfer agent to be used in the polymerization of the styrene copolymer resin includes, for example, α-methylstyrene linear dimer, n-dodecyl mercaptan, t-dodecyl mercaptan, n-octyl mercaptan, and the like.

As a polymerization method for the styrene copolymer resin, solution polymerization using polymerization solvent can be employed, if necessary. The polymerization solvent to be used includes aromatic hydrocarbons such as ethyl benzene, dialkyl ketones such as methyl ethyl ketone, and the like, and one type of the polymerization solvent may be used alone or two or more types may be used in combination. Other polymerization solvent, for example, aliphatic hydrocarbons can be further mixed with the aromatic hydrocarbons to the extent that the solubility of a polymerization product is not reduced. The polymerization solvent is preferably used to the extent of not exceeding 25 parts by mass relative to 100 parts by mass of the total monomer unit. When the polymerization solvent exceeds 25 parts by mass relative to 100 parts by mass of the total monomer unit, the polymerization speed decrease significantly, and the mechanical strength of the obtained resin tends to decrease significantly. Before polymerization, it is preferable to add 5 to 20 parts by mass of the polymerization solvent relative to 100 parts by mass of the total monomer unit, to facilitate uniform quality and to control polymerization temperature.

In the present embodiment, an apparatus used in a polymerization process to obtain the styrene copolymer resin is not particularly limited, and can be selected according to a polymerization method of the styrene-based resin. For example, when the bulk polymerization is employed, a polymerization apparatus constituted of one or more complete mixing reactors connected to each other can be used. There is no limitation on the devolatilization process. When the bulk polymerization is employed, polymerization is proceeded until a final unreacted monomer content is preferably less than 50 mass % and more preferably less than 40 mass %, and a volatile matter including unreacted monomer units is removed by a known devolatilization method. In more detail, an ordinary devolatilizer such as a flash drum, twin-shaft devolatilizer, thin-film evaporator, extruder, or the like can be used, but a devolatilizer with fewer retention parts are preferred. The temperature of the devolatilization process is usually of the order of 190° C. to 280° C., and is preferably 190° C. to 260° C. from the viewpoint of preventing formation of six-membered ring anhydride due to adjacency of the unsaturated carboxylic acid monomer unit (for example, methacrylic acid) and the unsaturated carboxylic acid ester monomer (for example, methyl methacrylate). The pressure of the devolatilization process is usually of the order of 0.13 kPa to 4.0 kPa, preferably 0.13 kPa to 3.0 kPa, and more preferably 0.13 kPa to 2.0 kPa. As a devolatilization method, for example, a method of removing volatiles by decompression under heat and a method of removing volatiles through an extruder or other equipment designed for volatile removal purpose.

In the present embodiment, the styrene-based resin is preferably a thermoplastic styrene-based resin because the thermoplastic styrene-based resin can reduce the amount of the catechol derivative, dimers of the styrene-based monomer units and trimers of the styrene-based monomer units. The thermoplastic styrene-based resin is also preferred from the standpoint of recycling and low cost. The thermoplastic styrene-based resin is defined as containing less than 4.5 mass % of a cross-linkable aromatic vinyl compound having two or more vinyl groups as a cross-linking component.

<Flame Retardant (B): (B) Component>

In the present embodiment, the styrene-based resin composition may contain a flame retardant (B) to provide flame retardance. The content of the flame retardant (B) is preferably 1 mass % to 30 mass %, more preferably 2 mass % to 20 mass %, and even more preferably 3 mass % to 15 mass %, relative to the total styrene-based resin composition (100 mass %). When the content is higher than 30 mass %, the dielectric constant and dielectric loss tangent become higher under usage environment, and yellowing change becomes large. In the present embodiment, the flame retardant (B) is preferably a phosphorus-based flame retardant, bromine-based flame retardant, or hindered amine compound (C2) from the viewpoint of a low dielectric constant and a low dielectric loss tangent. Among phosphorus-based flame retardants, compounds esterified with alkyl phenol and phosphinic acid compound (C1) are especially more effective at lowering the dielectric constant and dielectric loss tangent. Among bromine-based flame retardants, brominated diphenylalkanes, brominated phthalimides, and tris(polybromophenoxy)triazine compounds are more effective at lowering the dielectric constant and dielectric loss tangent. One type of the flame retardant may be used alone, or two or more types may be used in combination.

—Phosphorus-Based Flame Retardant—

The phosphorus-based flame retardant is not particularly limited, and one that can be obtained by a conventionally known method or a commercially available product can be used. Preferably, a phosphate ester compound, phosphazene compound, phosphonic acid compound, or phosphinic acid compound (C1) is used alone or in combination of two or more. Among these, the phosphate ester compound, phosphonic acid ester compound, or phosphinic acid compound (C1) is most preferred due to good compatibility with the styrene-based resin.

Phosphorus-based flame retardants, especially those with a phosphorus content of 3.0 mass % or more, can achieve a synergistic effect in flame retardance with (NOR-type) hindered amine compounds, and high flame retardance can be obtained with a small amount of addition. The phosphorus content of 3.0 mass % or more refers to 3.0 mass % or more of a phosphorus element contained in the phosphorus-based flame retardant in a phosphorous compound.

In the phosphorus-based flame retardant, the phosphorus content is preferably 3.0 mass % or more, and more preferably 7.0 mass % or more. When the phosphorus content is 3.0 mass % or more, a synergistic effect is generated with the (NOR-type) hindered amine compounds in flame retardance, and high flame retardance can be obtained with a small amount of addition, so this is effective at lowering the dielectric constant and dielectric loss tangent and at reducing variations in the dielectric constant and dielectric loss tangent under usage environment.

The phosphorus content can be determined by measuring the amount of phosphorus atoms contained in the phosphorus-based flame retardant by absorbance spectrophotometry.

As the phosphorus-based flame retardant, a flame retardant that is liquid at 150° C. to 300° C., that is, with a melting point of 300° C. or less is preferred for good dispersion in the styrene-based resin composition. When a phosphorus-based flame retardant that is solid when being melt-mixed (for example, a phosphorus-based flame retardant that does not have a melting point) is used, the phosphorus-based flame retardant is not in liquid form when being melt-mixed and therefore is not evenly dispersed in the (A1) component or (A2) component. This may cause decrease in physical properties and decrease in flame retardance.

—Phosphate Ester Compound—

As the phosphate ester compound, an aromatic phosphate ester compound is preferred. For example, there are monomeric phosphate ester compounds such as trimethyl phosphate (TMP), triethyl phosphate (TEP), triphenyl phosphate (TPP), tricresyl phosphate (TCP), tri-xylenyl phosphate (TXP), and credyldiphenylphosphate (CDP), aromatic condensed phosphate ester compounds, which are reaction products of phosphorus oxychloride, a divalent phenolic compound, and phenol (or alkyl phenol), such as resorcinol bis-dixylenyl phosphate, resorcinol bis-diphenyl phosphate, bisphenol A bis-diphenyl phosphate (BADP), bisphenol A bis-dicresyl phosphate, biphenol bis-dixylenyl phosphate, and biphenol bis-dixylenyl phosphate.

Among these, triphenyl phosphate (TPP), tricresyl phosphate (TCP), resorcinol bis-dixyrenyl phosphate, resorcinol bis-diphenyl phosphate, bisphenol A bis-diphenyl phosphate (BADP), biphenol bis-diphenyl phosphate, or biphenol bis-dixylenyl phosphate is preferred, triphenyl phosphate (TPP), resorcinol bis-dixylenyl phosphate, or resorcinol bis-diphenyl phosphate is more preferred, and resorcinol bis-diphenyl phosphate is even more preferred.

The phosphate ester compound is preferably a condensed phosphate ester compound of a condensation type, in terms of high heat resistance, reduction of mold deposit during a molding process, and the like. In particular, an aromatic condensed phosphate ester compound represented by the following chemical formula (II) is preferred.

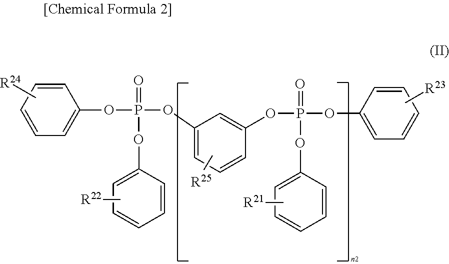

(In the above chemical formula (II), R^{2′} to R²⁵ are each independently a hydrogen atom, alkyl group with 1 to 10 carbons, cycloalkyl group with 3 to 20 carbons, aryl group with 6 to 20 carbons, alkoxy group with 1 to 10 carbons, or halogen atom, and R²¹ to R²⁵ may be the same or different. n2 is an integer of 0 to 30, preferably an integer of 0 to 10.)

The above alkyl group includes a methyl group, ethyl group, propyl group, isopropyl group, butyl group, isobutyl group, sec-butyl group, tert-butyl group, amyl group, tert-amyl group, hexyl group, 2-ethylhexyl group, n-octyl group, nonyl group, decyl group, and the like.

The above cycloalkyl group includes a cyclohexyl group and the like.

The above aryl group includes a phenyl group, kresyl group, xylyl group, 2,6-xylyl group, 2,4,6-trimethyl phenyl group, butyl phenyl group, nonyl phenyl group, and the like.

The above alkoxy group includes a methoxy group, ethoxy group, propoxy group, butoxy group, and the like.

The above halogen atom includes a fluorine atom, chlorine atom, bromine atom, and the like.

Furthermore, among the above phosphate ester compounds, from the viewpoint of both flame retardance and transparency, a phosphate ester compound represented by the following compound (II-1), (II-2), or (II-3) is preferred, a compound (II-2) or (II-3) is more preferred, and a compound (II-2) is even more preferred.

As the compound (II-2) (resorcinol bis-dixylenyl phosphate), for example, PX-200 of Daihachi Chemical Industry Co., Ltd. or the like can be used. As the compound (II-3) (resorcinol bis-diphenyl phosphate), for example, CR-733S of Daihachi Chemical Industry Co., Ltd. or the like can be used.

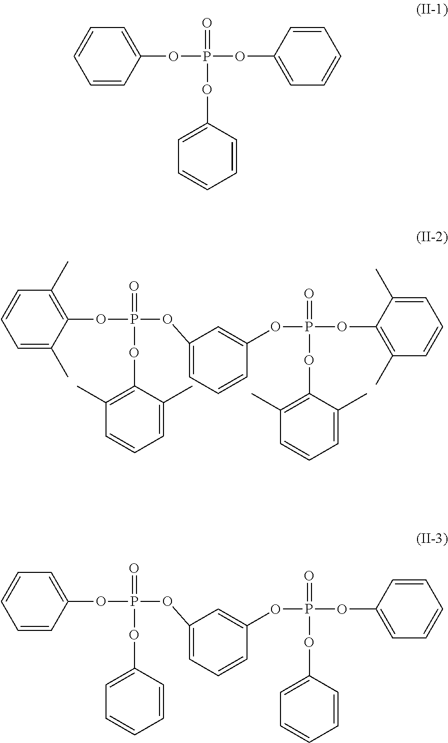 [SMILES: O=P(Oc1ccccc1)(Oc1ccccc1)Oc1ccccc1 ; Cc1cccc(C)c1OP(=O)(Oc1cccc(OP(=O)(Oc2c(C)cccc2C)Oc2c(C)cccc2C)c1)Oc1c(C)cccc1C ; O=P(Oc1ccccc1)(Oc1ccccc1)Oc1cccc(OP(=O)(Oc2ccccc2)Oc2ccccc2)c1]

—Phosphazene Compound—

The phosphazene compound includes, for example, 1,1,3,3,5,5-hexa(methoxy)cyclotriphosphazene, 1,1,3,3,5,5-hexa(ethoxy)cyclotriphosphazene, 1,1,3,3,5,5-hexa(n-propoxy)cyclotriphosphazene, 1,1,3,3,5,5-hexa(iso-propoxy)cyclotriphosphazene, 1,1,3,3,5,5-hexa(n-butoxy)cyclotriphosphazene, 1,1,3,3,5,5-hexa(iso-butoxy)cyclotriphosphazene, 1,1,3,3,5,5-hexa(phenoxy)cyclotriphosphazene, 1,1,3,3,5,5-hexa(p-tolyloxy)cyclotriphosphazene, 1,1,3,3,5,5-hexa(m-tolyloxy)cyclotriphosphazene, 1,1,3,3,5,5-hexa(o-tolyloxy)cyclotriphosphazene, 1,1,3,3,5,5-hexa(4-ethylphenoxy)cyclotriphosphazene, 1,1,3,3,5,5-hexa(4-n-propylphenoxy)cyclotriphosphazene, 1,1,3,3,5,5-hexa(4-iso-propylphenoxy)cyclotriphosphazene, 1,1,3,3,5,5-hexa(4-t-butylphenoxy)cyclotriphosphazene, 1,1,3,3,5,5-hexa(4-t-octylphenoxy)cyclotriphosphazene, 1,1,3,3,5,5-hexa(2,3-dimethylphenoxy)cyclotriphosphazene, 1,1,3,3,5,5-hexa(2,4-dimethylphenoxy)cyclotriphosphazene, 1,1,3,3,5,5-hexa(2,5-dimethylphenoxy)cyclotriphosphazene, 1,1,3,3,5,5-hexa(2,6-dimethylphenoxy)cyclotriphosphazene, 1,3,5-tris(methoxy)-1,3,5-tris(phenoxy)cyclotriphosphazene, 1,3,5-tris(ethoxy)-1,3,5-tris(phenoxy)cyclotriphosphazene, 1,3,5-tris(n-propoxy)-1,3,5-tris(phenoxy)cyclotriphosphazene, 1,3,5-tris(iso-propoxy)-1,3,5-tris(phenoxy)cyclotriphosphazene, 1,3,5-tris(n-butoxy)-1,3,5-tris(phenoxy)cyclotriphosphazene, 1,3,5-tris(i so-butoxy)-1,3,5-tris(phenoxy)cyclotriphosphazene, 1,3,5-tris(methoxy)-1,3,5-tris(p-tolyloxy)cyclotriphosphazene, 1,3,5-tris(methoxy)-1,3,5-tris(m-tolyloxy)cyclotriphosphazene, 1,3,5-tris(methoxy)-1,3,5-tris(o-tolyloxy)cyclotriphosphazene, 1,3,5-tris(ethoxy)-1,3,5-tris(p-tolyloxy)cyclotriphosphazene, 1,3,5-tris(ethoxy)-1,3,5-tris(m-tolyloxy)cyclotriphosphazene, 1,3,5-tris(ethoxy)-1,3,5-tris(o-tolyloxy)cyclotriphosphazene, 1,3,5-tris(n-propoxy)-1,3,5-tris(p-tolyloxy)cyclotriphosphazene, 1,3,5-tris(n-propoxy)-1,3,5-tris(m-tolyloxy)cyclotriphosphazene, 1,3,5-tris(n-propoxy)-1,3,5-tris(o-tolyloxy)cyclotriphosphazene, 1,3,5-tris(iso-propoxy)-1,3,5-tris(p-tolyloxy)cyclotriphosphazene, 1,3,5-tris(n-butoxy)-1,3,5-tris(p-tolyloxy)cyclotriphosphazene, 1,3,5-tris(iso-butoxy)-1,3,5-tris(p-tolyloxy)cyclotriphosphazene, 1,3,5-tris(methoxy)-1,3,5-tris(4-t-butylphenoxy)cyclotriphosphazene, 1,3,5-tris(methoxy)-1,3,5-tris(4-t-octylphenoxy)cyclotriphosphazene, 1,3,5-tris(n-propoxy)-1,3,5-tris(4-t-butylphenoxy)cyclotriphosphazene, 1,3,5-tris(n-propoxy)-1,3,5-tris(4-t-octylphenoxy)cyclotriphosphazene, and the like.

Among these, 1,1,3,3,5,5-hexa(methoxy)cyclotriphosphazene, 1,1,3,3,5,5-hexa(ethoxy)cyclotriphosphazene, 1,1,3,3,5,5-hexa(phenoxy)cyclotriphosphazene, 1,1,3,3,5,5-hexa(p-tolyloxy)cyclotriphosphazene, 1,3,5-tris(methoxy)-1,3,5-tris(phenoxy)cyclotriphosphazene, and 1,3,5-tris(ethoxy)-1,3,5-tris(phenoxy)cyclotriphosphazene are preferred, 1,1,3,3,5,5-hexa(ethoxy)cyclotriphosphazene, 1,1,3,3,5,5-hexa(phenoxy)cyclotriphosphazene, and 1,3,5-tris(ethoxy)-1,3,5-tris(phenoxy)cyclotriphosphazene are more preferred, 1,1,3,3,5,5-hexa(phenoxy)cyclotriphosphazene is even more preferred.

—Phosphonic Acid Ester Compound—

Examples of the above phosphonic acid ester compound include those represented by the following chemical formula (III).

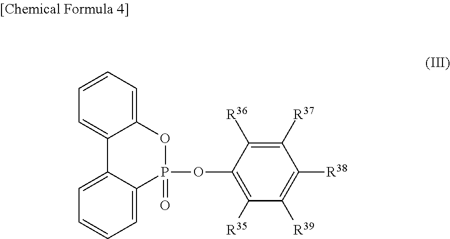

(In the above chemical formula (III), R³⁵ to R³⁹ are each independently a hydrogen atom or a monovalent hydrocarbon group that may have a substituent, and R⁶ to R¹⁰ may be identical or different.)

In this specification, the monovalent hydrocarbon group may be either chain (linear chain or branched chain) or ring (monocyclic ring, fused polycyclic ring, bridged ring, or spirocyclic ring), for example, a cyclic hydrocarbon group with a side chain. The hydrocarbon group may be either saturated or unsaturated.

The hydrocarbon group includes, for example, an alkyl group, cycloalkyl group, allyl group, aryl group, alkyl aryl group, aryl alkyl group, and the like.

Specific examples of the phosphonic acid ester compound represented by the above chemical formula (III) include compounds represented by the following formulas (III-1) to (III-8) below.

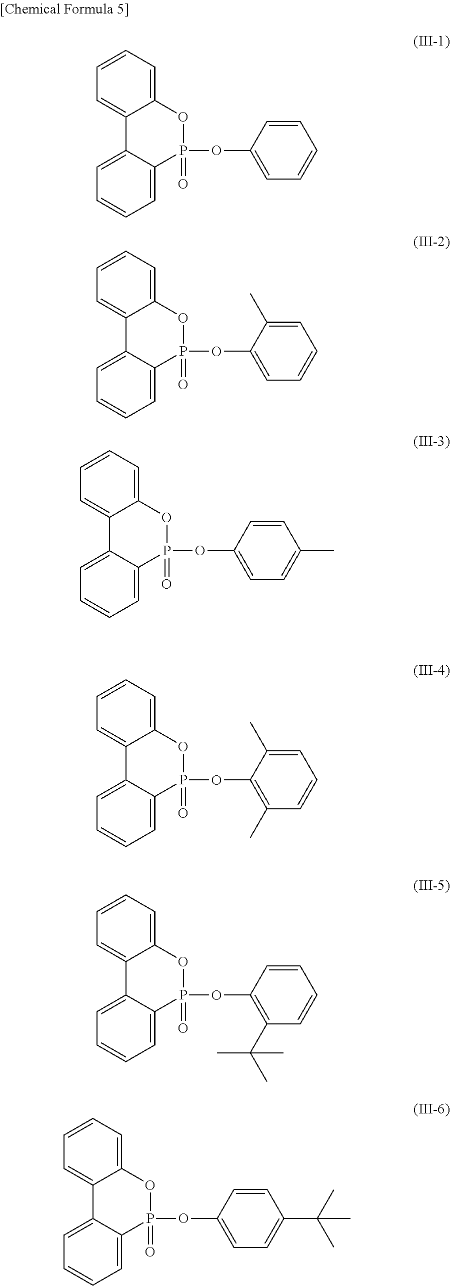

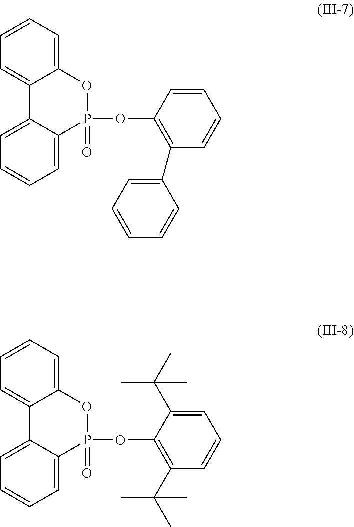 [SMILES: O=P1(Oc2ccccc2-c2ccccc2)Oc2ccccc2-c2ccccc21 ; CC(C)(C)c1cccc(C(C)(C)C)c1OP1(=O)Oc2ccccc2-c2ccccc21]

[Phosphinic Acid Compound (C1)]

As the phosphinic acid compound (C1) of the present embodiment, a compound represented by the general formula (IV), a compound represented by the general formula (V), and/or the like are/is preferred.

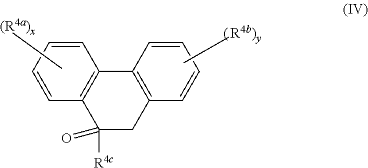

[In the above general formula (IV), R^{4a} and R^{4b} are each independently the same or different and indicate a hydrogen atom, a halogen atom, or a lower alkyl group. R^{4c} represents a hydrogen atom, a halogen atom, a hydroxyl group, a lower alkoxyl group, or a lower alkyl group. x and y each independently represent an integer from 1 to 4.]

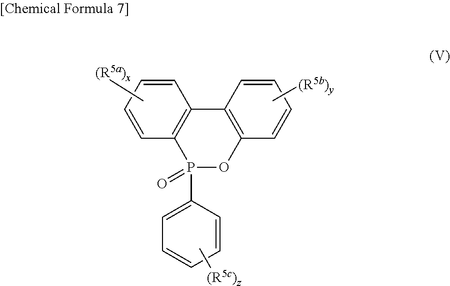

[In the above general formula (V), R^{5a} and R^{5b} are each independently the same or different and indicate a hydrogen atom, a halogen atom, or a lower alkyl group. R^{5c} is each independently the same or different and represents a hydrogen atom, a halogen atom, a hydroxyl group, a lower alkoxyl group, or a lower alkyl group. x and y each independently represent an integer from 1 to 4, and z represents an integer from 1 to 5.] From the viewpoint of superior color tone and flame retardance, the compound represented by the general formula (IV) is more preferred, and 9,10-dihydro-9-oxa phosphaphenanthrene-10-oxide is particularly preferred.

The term “lower alkoxy group, lower alkyl” in the general formula (IV) or (V) means a linear, branched or cyclic alkoxy group or alkyl group with 1 to 5 carbon atoms.

In the present embodiment, the phosphinic acid compound (C1) includes, for example, 9,10-dihydro-9-oxa-10-phosphaphenanthrene-10-oxide, or 10-benzyl-9,10-dihydro-9-oxa-10-phosphaphenanthrene-10-oxide, and the like. As 9,10-dihydro-9-oxa-10-phosphaphenanthrene-10-oxide, there is, for example, HCA of Sanko Inc. or the like. Also, as 10-benzyl-9,10-dihydro-9-oxa-10-phosphaphenanthrene-10-oxide can be used, for example, BCA of Sanko Inc. or the like can be used.

In the present embodiment, as the preferred content of the phosphorus flame retardant mentioned above in the styrene composition, the preferred content of the flame retardant (B) can be applied. In particular, the content of the phosphinic acid compound (C1) is preferably 1 mass % to 20 mass %, more preferably 1.5 mass % to 18 mass %, and even more preferably 2 mass % to 12 mass % relative to the total styrene-based resin composition (100 mass %).

[Hindered Amine Compound (C2)]

The hindered amine compound (C2) in the present embodiment is preferably a NOR-type hindered amine compound. When the NOR-type hindered amine compound is used as the hindered amine compound (C2), the synergistic effect with the flame retardant (B) is enhanced. Furthermore, when the hindered amine compound (C2) is used in combination with the phosphinic acid compound (C1) or the phosphonic acid ester, a high level of flame retardance can be obtained due to synergistic effect. The hindered amine compound (C2) is a well-known light stabilizer, and addition of the hindered amine compound (C2) can also impart light resistance.

An alkoxyimino group of the NOR (alkoxyimino group) type hindered amine compound (B) refers to one in which an imino group (>N—H) of a piperidine ring has the structure of an N-alkoxyl group (>N—OR), although the the imino group of the piperidine ring remains NH in an N—H type and is replaced by a methyl group in an N-methyl type. The N-alkoxyl group traps alkyl peroxy radicals (R′O₂.), which readily become radicals and exhibit flame retardant effects. On the other hand, in the case of the N-methyl or N—H hindered amine compound, there is a risk of decrease in flame retardance.

The above alkoxyl group (—OR) is not limited to an alkoxyl group with an oxygen bonded to an alkyl group, and R includes a cycloalkyl group, aralkyl group, aryl group, and the like, in addition to the alkyl group.

As specific examples of the alkoxyl group, a methoxy group, propoxy group, cyclohexyloxy group, and octyloxy group are preferred, and in particular, a propoxy group, cyclohexyloxy group, octyloxy group, and the like are preferred from the view point of larger molecular weight, which prevents bleedout from sheets and films.

The NOR-type hindered amine compound used in the present embodiment is not particularly limited as long as the NOR-type hindered amine compound has an N-alkoxyl group (>N—OR) structure. As suitable specific examples, there are NOR-type hindered amine compounds described in, for example, JP2002507238A, WO2005082852, and WO2008003605, and the like.

A polymer type of NOR-type hindered amine compound is particularly preferred. The polymer type generally refers to an oligomer or polymer compound. The polymer type reduces mold deposit in a molding process and is superior in terms of flame retardance and heat resistance.

For the above polymer type oligomer or polymer compound, the number of repeating units is preferably 2 to 100, more preferably 5 to 80.

Examples of the NOR-type hindered amine compound include the following compounds:
1-cyclohexyloxy-2,2,6,6-tetramethyl-4-octadecylaminopiperidine;
bis(1-octyloxy-2,2,6,6-tetramethylpiperidine-4-yl)sebacate;
2,4-bis[(1-cyclohexyloxy-2,2,6,6-tetramethylpiperidin yl)butylamino]-6-(2-hydroxyethylamino)-s-triazine;
bis(1-cyclohexyloxy-2,2,6,6-tetramethylpiperidin-4-yl)-adipate;
an oligomeric compound being a condensation product of 4,4′-hexamethylenebis(amino-2,2,6,6-tetramethylpiperidine) and 2,4-dichloro-6-[(1-octyloxy-2,2,6,6-tetramethylpiperidin yl)butylamino]-s-triazine end-capped with 2-chloro-4,6-bis(dibutylamino)-s-triazine;
an oligomeric compound being a condensation product of 4,4′-hexamethylenebis(amino-2,2,6,6-tetramethylpiperidine) and 2,4-dichloro-6-[(1-cyclohexyloxy-2,2,6,6-tetramethylpiperidin-4-yl)butylamino]-s-triazine end-capped with 2-chloro-4,6-bis(dibutylamino)-s-triazine;
2,4-bis[(1-cyclohexyloxy-2,2,6,6-piperidin-4-yl)-6-chloro-s-triazine;
a reaction product (N,N′,N′″-tris{2,4-bis[(1-cyclohexyloxy-2,2,6,6-tetramethylpiperidin-4-yl)n-butylamino]-s-triazine-6-yl}-3,3′-ethylenediiminodipropylamine) of peroxide-treated 4-butylamino-2,2,6,6-tetramethylpiperidine, 2,4,6-trichloro-s-triazine, cyclohexane, and N,N′-ethane-1,2-diylbis(1,3-propanediamine);
bis(1-undecanoxy-2,2,6,6-tetramethylpiperidin-4-yl)carbonate; 1-undecyloxy-2,2,6,6-tetramethylpiperidin-4-one; and
bis(1-stearyloxy-2,2,6,6-tetramethylpiperidin-4-yl)carbonate.

Commercially available NOR-type hindered amine compounds include FlamestabNOR116FF, TINUVIN NOR371, TINUVIN XT850FF, TINUVIN XT855FF, and TINUVIN PA123 produced by BASF, LA-77Y, LA-81 and FP-T80 produced by ADEKA Corporation, and the like.

One type of the NOR-type hindered amine compound may be used alone or two or more types may be used in combination.

The NOR-type hindered amine compound is a well-known light stabilizer, and addition of the NOR-type hindered amine compound can also impart light resistance.

In the present embodiment, as the preferred content of the above NOR-type hindered amine compound in the styrene composition, the preferred content of the flame retardant (B) can be applied.

The hindered amine light stabilizer includes, for example, hindered amine compounds such as 2,2,6,6-tetramethyl-4-piperidylstearate, 1,2,2,6,6-pentamethyl-4-piperidylstearate, 2,2,6,6-tetramethyl-4-piperidylbenzoate, bis(2,2,6,6-tetramethyl piperidyl) sebacate, bis(1,2,2,6,6-tetramethyl-4-piperidyl) sebacate, bis(1-octoxy-2,2,6,6-tetramethyl-4-piperidyl)sebacate, tetrakis(2,2,6,6-tetramethyl-4-piperidyl)-1,2,3,4-butane tetracarboxylate, tetrakis(1,2,2,6,6-pentamethyl-4-piperidyl)-1,2,3,4-butane tetracarboxylate, bis(2,2,6,6-tetramethyl piperidyl)di(tridecyl)-1,2,3,4-butane tetracarboxylate, bis(1,2,2,6,6-pentamethyl-4-piperidyl)di(tridecyl)-1,2,3,4-butane tetracarboxylate, bis(1,2,2,4,4-pentamethyl-4-piperidyl)-2-butyl-2-(3,5-di-tert-butyl-4-hydroxybenzyl)malonate, 1-(2-hydroxyethyl)-2,2,6,6-tetramethyl-4-piperidino/diethyl succinate polycondensate, 1,6-bis(2,2,6,6-tetramethyl-4-piperidylamino)hexane/2,4-dichloro-6-morpholino-s-triazine polycondensate, 1,6-bis(2,2,6,6-tetramethyl-4-piperidylamino)hexane/2,4-di chloro-6-tert-octylamino-s-triazine polycondensate, 1,5,8,12-tetrakis[2,4-bis(N-butyl-N-(2,2,6,6-tetramethyl-4-piperidyl)amino)-s-triazine-6-yl]-1,5,8,12-tetraazadododecane, 1,5,8,12-tetrakis[2,4-bis(N-butyl-N-(1,2,2,6,6-pentamethyl-4-piperidyl)amino)-s-triazine-6-yl]-1,5,8-12-tetraazadododecane, 1,6,11-tris[2,4-bis(N-butyl-N-(2,2,6,6-tetramethyl-4-piperidyl)amino)-s-triazine-6-yl]aminoundecane, and 1,6,11-tris[2,4-bis(N-butyl-N-(1,2,2,6,6-pentamethyl-4-piperidyl)amino)-s-triazine-6-yl]aminoundecane. One type of the hindered amine compounds may be used alone, or two or more types may be mixed and used in combination.

In particular, the content of the hindered amine compound (C2) is preferably 0.2 mass % to 3 mass %, more preferably 0.3 mass % to 2.5 mass %, and even more preferably 0.5 mass % to 2 mass % relative to the total styrene-based resin composition (100 mass %).

—Bromine-Based Flame Retardant—

As the bromine-based flame retardant of the present embodiment, a bromine-based flame retardant (brominated flame retardant) normally used in this field can be used without limitation, and there are flame retardants including a brominated bisphenol A-based or brominated bisphenol S-based compound (e.g., brominated bisphenol A compound, brominated bisphenol S compound, brominated phenyl ether, brominated bisphenol A-based carbonate oligomer, brominated bisphenol A-based epoxy resin), brominated phenyl ether, brominated bisphenol A-based carbonate oligomer, brominated bisphenol A-based epoxy resin, brominated styrene, brominated phthalimide, brominated benzene, brominated cycloalkane, and brominated isocyanurate as ones generally used among these. One type of the bromine-based flame retardant may be used alone, or two or more types may be used in combination.

The brominated bisphenol A-based or brominated bisphenol S-based compound is a compound in which one to eight bromine atoms are bonded to a benzene ring of a bisphenol A or bisphenol S residue. Examples of the compound include tetrabromobisphenol A, tetrabromobisphenol A bis(2-hydroxyethyl ether), tetrabromobisphenol A bis(allyl ether), tetrabromobisphenol A bis(2-bromoethyl ether), tetrabromobisphenol A bis(3-bromopropyl ether), tetrabromobisphenol A bis(2,3-dibromopropyl ether), tetrabromobisphenol S, tetrabromobisphenol S bis(2-hydroxyethyl ether), tetrabromobisphenol S bis(2,3-dibromopropyl ether), and the like.

Commercially available brominated bisphenol A-based or brominated bisphenol S-based compounds include “FR-1524” produced by Bromochem Far East Co., Ltd., “Great Lakes BA-50”, “Great Lakes BA-50P”, “Great Lakes BA-59”, “Great Lakes BA-59P”, and “Great Lakes BA-68” produced by Great Lakes Chemical Corporation, “Saytex RB-100” produced by Albemarle Corporation, “Fireguard 2000”, “Fireguard 3000”, “Fire guard 3100”, and “Fireguard 3600” produced by Teijin Chemicals Ltd., “Non Nen PR-2” produced by Marubishi Oil Chemical Corporation, “Flame Cut 121R” produced by Tosoh Corporation, and “Fire Cut P-680” produced by Suzuhiro Chemical Co., Ltd., and the like.

Brominated phenyl ether is compounds in which one or more bromine atoms are bonded to a phenyl ether group, and includes bis(tribromophenoxy)ethane, hexabrom diphenyl ether, octabrom diphenyl ether, decabrom diphenyl ether, polydibromophenylene oxide, and the like.

Commercially available brominated phenyl ether flame retardants include “FR-1210” and “FR-1208” produced by Bromochem Far East Co., Ltd., “Great Lakes FF-680”, “Great Lakes DE-83”, “Great Lakes DE-83R”, and “Great Lakes DE-79” produced by Great Lakes Chemical Corporation, “Saytex 102E” and “Saytex 111” produced by Albemarle Corporation, and the like.

The above brominated bisphenol A-based compound is preferably a compound having the chemical structure represented by the following chemical formula (VI), and includes oligomers and polymers.

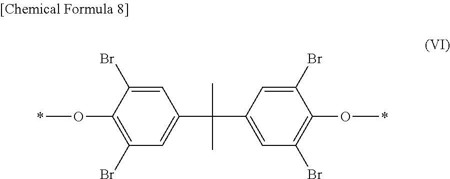

(In the above chemical formula (VI), * represents a bonding hand.)

Brominated bisphenol A-based carbonate oligomers, which are examples of the compounds represented by the above chemical formula (VI), are preferably polymerized products having a group represented by the following chemical formula (VI-1).

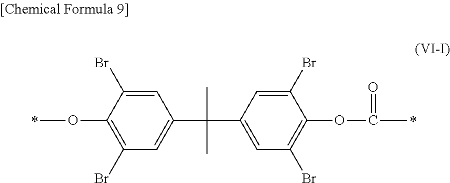 [SMILES: COc1c(Br)cc(C(C)(C)c2cc(Br)c(OC(C)=O)c(Br)c2)cc1Br]

Oligomers refer to those having a degree of polymerization of 1 to 10. In the above chemical formula (VI-1), * represents a bonding hand.

Polymers of the group represented by the above chemical formula (VI-1) include flame retardants represented by, for example, the following compounds (VI-2) or (VI-3).

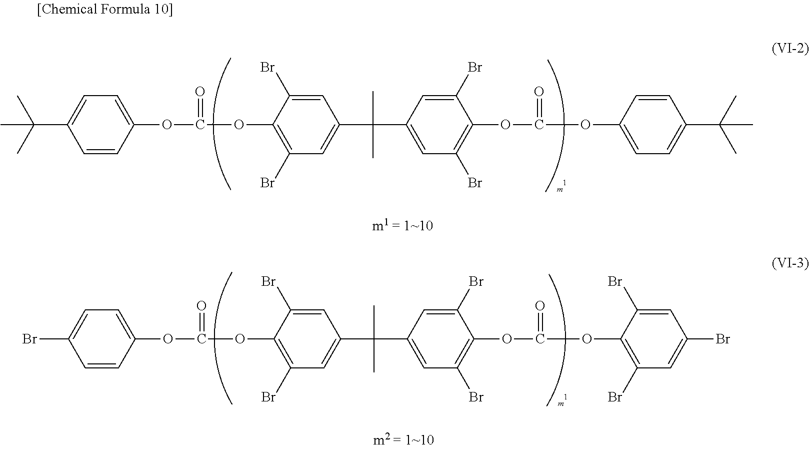

Commercially available flame retardants of the above compound (VI-1) include “Fireguard 7000” and “Fireguard 7500” from Teijin Chemicals Ltd.

Commercially available flame retardants of the above compound (VI-2) include “Great Lakes BC-52” and “Great Lakes BC-58” by Great Lakes Chemical Corporation and the like.

The brominated bisphenol A-based epoxy resin, which is an example of the compounds represented by the above chemical formula (VI), includes a compound represented by the following compound (VII).

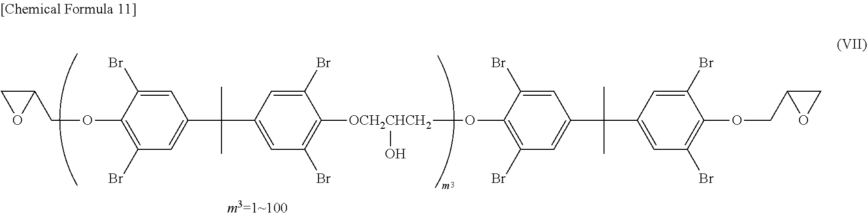

There are various commercially available flame retardants with the above chemical formula (VII), depending on the degree of polymerization (m³), such as “F-2300”, “F-2300H”, “F-2400”, and “F-2400H” produced by Bromochem Far East Co., Ltd., “PRATHERM EP-16”, “PRATHERM EP-30”, “PRATHERM EP-100”, and “PRATHERM EP-500” produced by DIC Corporation, and “SR-T 1000”, “SR-T2000”, “SR-T5000”, and “SR-T20000” produced by Sakamoto Yakuhin Kogyo Co., Ltd.

Examples of the brominated bisphenol A-based epoxy resin include compounds in which both terminal epoxy groups of the above formula (VII) are blocked with a blocking agent and compounds in which one terminal epoxy group is blocked with a blocking agent. The blocking agent is not limited as long as the blocking agent is a compound that ring-opening adds an epoxy group, but includes phenols, alcohols, carboxylic acid, amines, isocyanates, and other compounds containing bromine atoms. Among these, brominated phenols are preferred in terms of improving flame retardant effects, such as dibromophenol, tribromophenol, pentabromophenol, ethyl dibromophenol, propyl dibromophenol, butyl dibromophenol, and dibromocresol.

Examples of the flame retardants in which both terminal epoxy groups of the polymer are blocked with the blocking agent include flame retardants represented by the following compound (VII-1) or (VII-2).

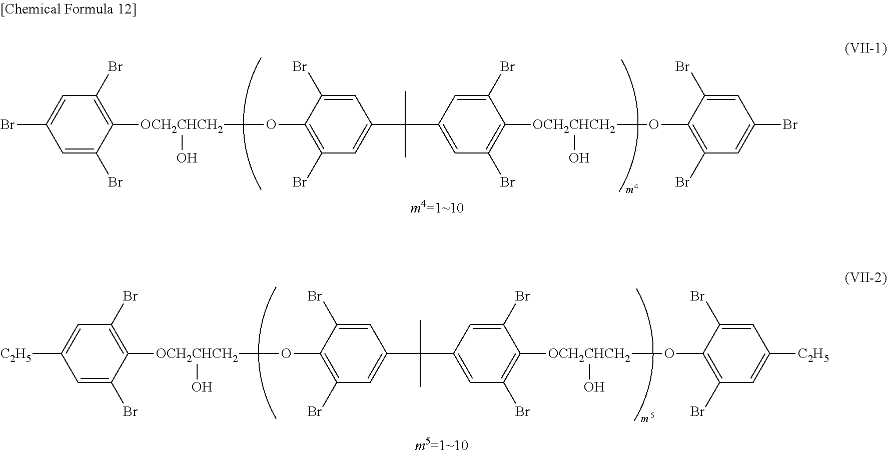

Commercially available flame retardants of the above compound (VII-1) or (VII-2) include “PRATHERM EC-14”, “PRATHERM EC-20”, and “PRATHERM EC-30” produced by DIC Corporation, “TB-60” and “TB-62” produced by TOHTO Chemical Co., Ltd., “SR-T3040” and “SR-T7040” produced by Sakamoto Yakuhin Kogyo Co., Ltd., and the like.

Examples of the flame retardants in which one terminal epoxy group of the polymer is blocked with the blocking agent include flame retardants represented by the following compound (VII-3) or (VII-4).

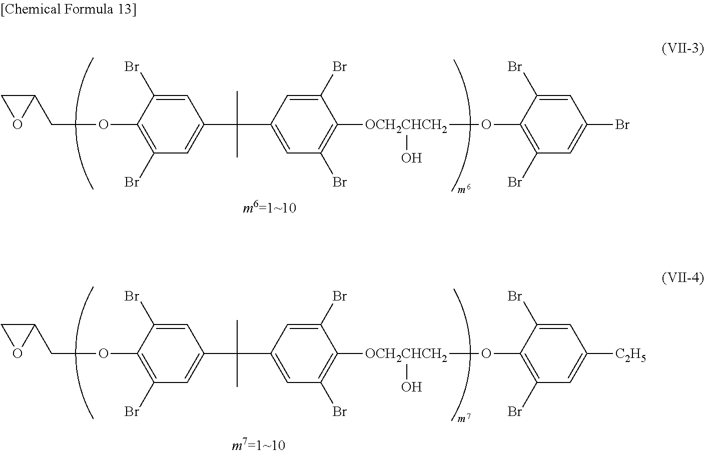

Commercially available flame retardants of the above compound (VII-3) or (VII-4) include “PRATHERM EPC-15F” produced by DIC Corporation, “E5354” produced by Petrochemical Shell Epoxy Co., Ltd., and the like.

The brominated styrene flame retardant includes a brominated styrene monomer with the following chemical formula (VIII) in which one to five bromine atoms are bonded to a benzene ring of a styrene backbone, and a polymer of the chemical formula (VIII), i.e., a polymer having repeating units of the following chemical formula (VIIIa), and the polymer is preferred.

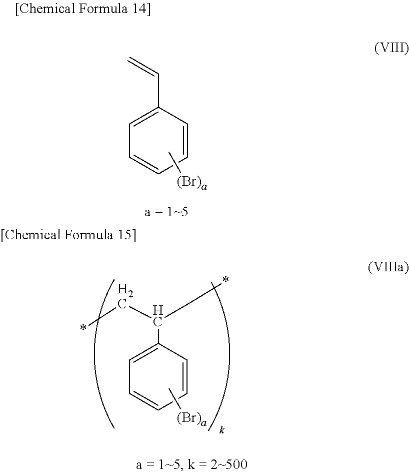

Examples of brominated styrene flame retardant include, for example, bromstyrene and brominated polystyrene. Commercially available brominated polystyrene flame retardants include “Great Lakes PDBS-10” and “Great Lakes PDBS-80” produced by Great Lakes Chemical Corporation and the like. “PYRO-CHEK 68PB” produced by Ferro Corporation can also be cited as an example of the brominated polystyrene flame retardant, although its manufacturing process differs from that of the aforementioned flame retardants.

The brominated phthalimide flame retardant is a compound with one to four bromine atoms are bonded to a benzene ring of a phthalimide group, and includes, for example, monobromophthalimide, dibromophthalimide, tribromophthalimide, tetrabromophthalimide, ethylenebis(monobromophthalimide), ethylenebis(dibromophthalimide), ethylenebis(tribromophthalimide), and ethylenebis(tetrabromophthalimide) of the following chemical formula (IX).

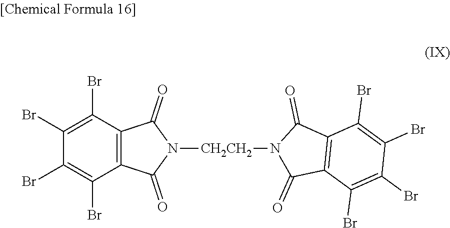

Commercially available flame retardants include “Saytex BT-93” and “Saytex BT-93W” produced by Albemarle Corporation.

Brominated benzenes are compounds consisting of one or more bromine atoms bonded to a benzene ring, such as tetrabromobenzene, pentabromobenzene, hexabrombenzene, bromophenyl allyl ether, pentabromotoluene, 1,1-bis(pentabromophenyl)ethane, 1,2-bis(pentabromophenyl)ethane, and poly(pentabromobenzyl acrylate). Commercially available flame retardants include “Saytex 8010” produced by Albemarle Corporation.

Brominated cycloalkanes include brominated hydrocarbons with one to six bromine atoms bonded to cycloalkanes (cyclic aliphatic hydrocarbons) with 6 to 12 carbons. Examples of the cycloalkanes include cyclohexane and cyclododecane. Examples of the brominated cycloalkanes include pentabromocyclohexane, hexabromocyclohexane, tetrabromocyclododecane, pentabromocyclododecane, and hexabromocyclododecane, and the like.

Commercially available hexabromocyclododecanes include “FR-1206” produced by Bromochem Far East Co., Ltd., “Saytex HBCD” produced by Albemarle Corporation, “Great Lakes CD-75P” produced by Great Lakes Chemical Corporation, “Fire Cut P-880M” produced by Suzuhiro Chemical Co., Ltd., “PYROGUARD SR-103” produced by Dai-ichi Kogyo Seiyaku Co., Ltd., and the like.

Brominated isocyanurates include compounds consisting of a brominated alkyl group with a bromine atom bonded to a 2 to 6 carbon alkyl group (chained aliphatic hydrocarbon group) and an isocyanuric acid residue, and compounds consisting of a brominated phenoxy group with 1 to 5 brom atoms bonded to a phenoxy group and an isocyanuric acid residue. Examples of the brominated isocyanurates include tris(monobromopropyl)isocyanurate, tris(2,3-dibromopropyl)isocyanurate, tris(tribromopropyl)isocyanurate, tris(tetrabromopropyl)isocyanurate, tris(pentabromopropyl)isocyanurate, tris(heptabromopropyl)isocyanurate, tris(octabromobutyl)isocyanurate, tris(monobromophenoxy)isocyanurate, tris(dibromophenoxy)isocyanurate, tris(tribromophenoxy)isocyanurate, tris(pentabromophenoxy)isocyanurate, tris(ethylmonobromophenoxy)isocyanurate, tris(propyldibromophenoxy)isocyanurate, and the like.

Commercially available brominated isocyanurates include “TAIC-6B” produced by Nihon Kasei Co., Ltd. and “Fire Cut P-660” produced by Suzuhiro Chemical Co., Ltd., and the like.

In addition to the aforementioned general-purpose brominated flame retardants, those described in literatures and in catalogs of brominated flame retardant manufacturers can of course be used. Brominated phenols, brominated phenoxytriazines, brominated alkanes, brominated maleimides, brominated phthalates, and the like can be listed as such brominated flame retardants.

Brominated phenols are compounds in which one to five bromine atoms are bonded to a phenol group, and include monobromophenol, dibromophenol, tribromophenol, tetrabromophenol, pentabromophenol, and the like.

Brominated phenoxytriazines are compounds in which one to five bromine atoms are bonded to a phenoxy group and one to three of the brominated phenoxy groups are bonded to a triazine ring, and include, for example, mono(tribromophenoxy)triazine, bis(monobromophenoxy)triazine, bis(tribromophenoxy)triazine, tris(dibromophenoxy)triazine, tris(tribromophenoxy)triazine, and the like. As a commercially available flame retardant, there is “PYROGUARD SR-245” produced by Dai-ichi Kogyo Seiyaku Co., Ltd.

Brominated alkanes are compounds in which a bromine atom is bonded to an alkane (chained aliphatic hydrocarbon) with 2 to 6 carbons. Examples of alkanes include ethane, propane, butane, pentane, and hexane. Examples of brominated alkanes include dibromoethane, tetrabromoethane, monobromopropane, tribromopropane, hexabromopropane, octabromopropane, tetrabromobutane, hexabromobutane, octabromobutane, tribromopentane, pentabromopentane, octabromopentane, dibromohexane, tribromohexane, tetrabromohexane, hexabromohexane, octabromohexane, and the like.

Brominated maleimides are compounds in which one to five bromine atoms are bonded to a phenylmaleimide group, and include, for example, monobromophenylmaleimide, dibromophenylmaleimide, tribromophenylmaleimide, pentabromophenylmaleimide, and the like.

Brominated phthalates include compounds in which one to four bromine atoms are bonded to a phthalic anhydride, and include monobromo phthalic anhydride, dibromo phthalic anhydride, tribromo phthalic anhydride, tetrabromo phthalic anhydride, and the like.

It is also common to use a flame retardant promoter such as antimony trioxide to further enhance flame retardance, but the addition of such flame retardant promoter does not affect the effect of the present disclosure in any way.

The amount of addition of the flame retardant promoter is normally 0.5 parts by mass to 10 parts by mass per 100 parts by mass of polystyrene, but is preferably 1 part by mass to 7 parts by mass in relation to physical properties and the like.

In the present embodiment, as the preferred content of the aforementioned brominated flame retardant in the styrene composition, the preferred content of the flame retardant (B) can be applied.

<Optional Additives>

In addition to the above styrene-based resin (A1), catechol derivative (4-t-butyl catechol), and optional flame retardant (B), optional additives such as conventionally known additives and processing promoters can be added as needed to the styrene-based resin composition of the present embodiment to the extent that the effects of the present disclosure are not impaired. These additives, processing promoters, and the like include antioxidants, weather resistance agents, lubricants, antistatic agents, fillers, and the like.

The antioxidants include phenolic compounds, phosphorous compounds, thioether compounds, and the like.

The above phenolic antioxidants include, for example, 2,6-di-tert-butyl-p-cresol, 2,6-diphenyl-4-octadecyloxyphenol, distearyl(3,5-di-tert-butyl-4-hydroxybenzyl)phosphonate, 1,6-hexamethylenebis[(3,5-di-tert-butyl-4-hydroxyphenyl)propionic acid amide], 4,4′-thiobis(6-tert-butyl-m-cresol), 2,2′-methylenebis(4-methyl-6-tert-butylphenol), 2,2′-methylenebis(4-ethyl-6-tert-butylphenol), 4,4′-butylidenebis(6-tert-butyl-m-cresol), 2,2′-ethylidenebis(4,6-di-tert-butylphenol), 2,2′-ethylidenebis(4-sec-butyl-6-tert-butylphenol), 1,1,3-tris(2-methyl-4-hydroxy-5-tert-butylphenyl)butane, 1,3,5-tris(2,6-dimethyl-3-hydroxy-4-tert-butylbenzyl)isocyanurate, 1,3,5-tris(3,5-di-tert-butyl-4-hydroxybenzyl)isocyanurate, 1,3,5-tris(3,5-di-tert-butyl-4-hydroxybenzyl)-2,4,6-trimethylbenzene, 2-tert-butyl-4-methyl-6-(2-acryloyloxy-3-tert-butyl-5-methylbenzyl)phenol, stearyl[3-(3,5-di-tert-butyl-4-hydroxyphenyl)propionate], tetrakis[3-(3,5-di-tert-butyl-4-hydroxyphenyl)methyl propionate]methane, thiodiethyleneglycolbis[(3,5-di-tert-butyl-4-hydroxyphenyl)propionate], 1,6-hexamethylenebis[(3,5-di-tert-butyl-4-hydroxyphenyl) propionate], bis[3,3-bis(4-hydroxy-3-tert-butylphenyl) butyric acid] glycol ester, bis[2-tert-butyl-4-methyl-6-(2-hydroxy-3-tert-butyl-5-methylbenzyl)phenyl]terephthalate, 1,3,5-tris[(3,5-di-tert-butyl-4-hydroxyphenyl)propionyloxyethyl]isocyanurate, 3,9-bis[1,1-dimethyl-2-{(3-tert-butyl-4-hydroxy-5-methylphenyl)propionyloxy}ethyl]-2,4,8,10-tetraoxaspiro[5,5]undecane, triethyleneglycolbis[(3-tert-butyl-4-hydroxy-5-methylphenyl)propionate], and the like. One type of these may be used alone, or two or more types may be mixed and used.

The above phosphorus antioxidants include, for example, tris(2,4-di-tert (2,4-di-tert-butylphenyl)phosphite, trisnonylphenyl phosphite, tris[2-tert-butyl-4-(3-tert-butyl-4-hydroxy methylphenylthio)-5-methylphenyl]phosphite, tridecyl phosphite, octyl diphenyl phosphite, di(decyl)monophenyl phosphite, di(tridecyl)pentaerythritol diphosphite, di(nonylphenyl)pentaerythritol diphosphite, bis(2,4-di-tert-butylphenyl)pentaerythritol diphosphite, bis(2,6-di-tert-butyl-4-methylphenyl)pentaerythritol diphosphate, bis(2,4,6-tri-tert-butylphenyl)pentaerythritol diphosphate, bis(2,4-dicumylphenyl)pentaerythritol diphosphite, tetra(tridecyl)isopropylidene diphenol diphosphite, tetra(tridecyl)-4,4′-n-butylidenebis(2-tert-butyl-5-methylphenol)diphosphite, hexa(tridecyl)-1,1,3-tris(2-methyl-4-hydroxy-5-tert-butylphenyl)butanetriphosphite, tetrakis(2,4-di-tert-butylphenyl)biphenylenediphosphonite, 9,10-dihydro-9-oxa-10-phosphaphenanthrene-10-oxide, 2,2′-methylenebis(4,6-tert-butylphenyl)-2-ethylhexylphosphite, 2,2′-methylenebis(4,6-tert-butylphenyl)-octadecyl phosphite, 2,2′-ethylidenebis(4,6-di-tert-butylphenyl)fluorophosphite, tris(2-[(2,4,8,10-tetrakis-tert-butyl-dibenzo[d,f][1,3,2]dioxaphosphine-6-yl)oxy]ethyl)amine, phosphite of 2-ethyl-2-butylpropylene glycol and 2,4,6-tri-tert-butylphenol, and the like. One type of these may be used alone, or two or more types may be mixed and used.

The thioether antioxidants include, for example, dialkyl thiodipropionates such as dilauryl thiodipropionate, dimyristyl thiodipropionate, and distearyl thiodipropionate, and pentaerythritol tetra(β-alkylmercaptopropionate)esters. One type of these may be used alone, or two or more types may be mixed and used.

As the above weather resistance agents, UV absorbers, hindered amine light stabilizers, and the like can be used.

The above UV absorbers include, for example: 2-hydroxybenzophenones such as 2,4-dihydroxybenzophenone, 2-hydroxy-4-methoxybenzophenone, 2-hydroxy-4-octoxybenzophenone, and 5,5′-methylenebis(2-hydroxy-4-methoxybenzophenone); 2-(2′-hydroxyphenyl)benzotriazoles such as 2-(2′-hydroxy-5′-methylphenyl)benzotriazole, 2-(2′-hydroxy-3′,5′-di-tert-butylphenyl)-5-chlorobenzotriazole, 242′-hydroxy-3′-tert-butyl methylphenyl)-5-chlorobenzotriazole, 2-(2′-hydroxy-5′-tert-octylphenyl)-benzotriazole, 2-(2′-hydroxy-3′,5′-dicumylphenyl)benzotriazole, 2,2′-methylenebis(4-tert-octyl (benzotriazolyl)phenol), and 2-(2′-hydroxy-3′-tert-butyl-5′-carboxyphenyl)benzotriazole; benzoates such as phenylsalicylate, resorcinol monobenzoate, 2,4-di-tert-butylphenyl-3,5-di-tert-butyl-4-hydroxybenzoate, 2,4-di-tert-amylphenyl-3,5-di-tert-butyl-4-hydroxybenzoate, and hexadecyl-3,5-di-tert-butyl-4-hydroxybenzoate; substituted oxanilides such as 2-ethyl-2′-ethoxyoxanilide and 2-ethoxy-4′-dodecyloxanilide; cyanoacrylates such as ethyl-α-cyano-β, β-diphenylacrylate, and methyl-2-cyano-3-methyl-3-(p-methoxyphenyl)acrylate; and triaryl triazines such as 2-(2-hydroxy-4-octoxyphenyl)-4,6-bis(2,4-di-tert-butylphenyl)-s-triazine, 2-(2-hydroxy-4-methoxyphenyl)-4,6-diphenyl-s-triazine, and 2-(2-hydroxy-4-propoxy-5-methylphenyl)-4,6-bis(2,4-di-tert-butylphenyl)-s-triazine. One type of these may be used alone, or two or more types may be mixed and used.

The above hindered amine light stabilizers include, for example, hindered amine compounds such as 2,2,6,6-tetramethyl-4-piperidylstearate, 1,2,2,6,6-pentamethyl-4-piperidylstearate, 2,2,6,6-tetramethyl-4-piperidylbenzoate, bis(2,2,6,6-tetramethyl-4-piperidyl)sebacate, bis(1,2,2,6,6-tetramethyl-4-piperidyl)sebacate, bis(1-octoxy-2,2,6,6-tetramethyl-4-piperidyl)sebacate, tetrakis(2,2,6,6-tetramethyl-4-piperidyl)-1,2,3,4-butanetetracarboxylate, tetrakis(1,2,2,6,6-pentamethyl-4-piperidyl)-1,2,3,4-butanetetracarboxylate, bis(2,2,6,6-tetramethyl-4-piperidyl)di(tri decyl)-1,2,3,4-butanetetracarboxylate, bis(2,2,6,6-tetramethyl-4-piperidyl)di(tri decyl)-1,2,3,4-butane tetracarboxylate bis(1,2,2,6,6-pentamethyl-4-piperidyl)di(tridecyl)-1,2,3,4-butanetetracarboxylate, bis(1,2,2,4,4-pentamethyl-4-piperidyl)-2-butyl-2-(3,5-di-tert-butyl-4-hydroxybenzyl)malonate, 1-(2-hydroxyethyl)-2,2,6,6-tetramethyl-4-piperidinol/di ethyl succinate polycondensate, 1,6-bis(2,2,6,6-tetramethyl-4-piperidylamino)hexane/2,4-di chloro-6-morpholino-s-triazine polycondensate, 1,6-bis(2,2,6,6-tetramethyl piperidylamino)hexane/2,4-di chloro-6-tert-octylamino-s-triazine polycondensate, 1,5,8,12-tetrakis[2,4-bis(N-butyl-N-(2,2,6,6-tetramethyl-4-piperidyl)amino)-s-triazine-6-yl]-1,5,8,12-tetraazadododecane, 1,5,8,12-tetrakis[2,4-bis(N-butyl-N-(1,2,2,6,6-pentamethyl-4-piperidyl)amino)-s-triazine-6-yl]-1,5,8-12-tetraazadododecane, 1,6,11-tris[2,4-bis(N-butyl-N-(2,2,6,6-tetramethyl-4-piperidyl)amino)-s-triazine-6-yl]aminoundecane, and 1,6,11-tris[2,4-bis(N-butyl-N-(1,2,2,6,6-pentamethyl-4-piperidyl)amino)-s-triazine-6-yl]aminoundecane.

One type of these may be used alone, or two or more types may be mixed and used.

As the above lubricants, fatty acid amides, fatty acid esters, fatty acid, fatty acid metal salts, and the like can be used.

The aliphatic amide lubricants include stearic acid amides, oleic acid amides, erucic acid amides, behenic acid amides, ethylene bis-stearic acid amides, ethylene bis-oleic acid amides, ethylene bis-erucic acid amides, and ethylene bis-lauryl acid amides.

One type of these may be used alone, or two or more types may be mixed and used.

The above aliphatic ester lubricants include methyl laurate, methyl myristate, methyl palmitate, methyl stearate, methyl oleate, methyl erucate, methyl behenate, butyl laurylate, butyl stearate, isopropyl myristate, isopropyl palmitate, octyl palmitate, coconut fatty acid octyl ester, octyl stearate, bovine fat fatty acid octyl ester, lauryl laurate, stearyl stearate, behenyl behenate, cetyl myristate, ester of linear and unbranched saturated monocarboxylic acid (hereafter abbreviated as montanic acid) with 28 to 30 carbons and ethylene glycol, ester of montanic acid and glycerin, ester of montanic acid and butylene glycol, ester of montanic acid and trimethylolethane, ester of montanic acid and trimethylol propane, ester of montanic acid and pentaerythritol, glycerol monostearate, sorbitan monolaurate, sorbitan monopalmitate, sorbitan monostearate, sorbitan monooleate, sorbitan sesquioleate, sorbitan triolate, polyoxyethylene sorbitan monolaurate, polyoxyethylene sorbitan monopalmitate, polyoxyethylene sorbitan monostearate, polyoxyethylene sorbitan monooleate, polyoxyethylene sorbitan triolate, and the like. One type of these may be used alone, or two or more types may be mixed and used.

Among the above fatty acid lubricants, saturated fatty acid includes, in the concrete, lauric acid (dodecanoic acid), isodecanoic acid, tridecyl acid, myristic acid (tetradecanoic acid), pentadecyl acid, palmitic acid (hexadecanoic acid), malgaric acid (heptadecanoic acid), stearic acid (octadecanoic acid), isostearic acid, tuberculostearic acid (nonadecanoic acid), 2-hydroxystearic acid, arachidic acid (icosanoic acid), behenic acid (docosanoic acid), lignoseric acid (tetradocosanoic acid), serotinic acid (hexadocosanoic acid), montanic acid (octadocosanoic acid), melicinic acid, and the like, and particularly include lauric acid, palmitic acid, stearic acid, behenic acid, 12-hydroxystearic acid, montanic acid, and the like.

Among the above fatty acid lubricants, unsaturated fatty acid includes, in the concrete, myristoleic acid (tetradecenoic acid), palmitoleic acid (hexadecenoic acid), oleic acid (cis-9-octadecenoic acid), elaidic acid (trans-9-octadecenoic acid), ricinoleic acid (octadecadienoic acid), baccenic acid (cis-11-octadecenoic acid), linoleic acid (octadecadienoic acid), linolenic acid (9,11,13-octadecatrienoic acid), elestearic acid (9,11,13-octadecatrienoic acid), gadoleic acid (icosanoic acid), erucic acid (docosanoic acid), nelvonic acid (tetradocosanoic acid), and the like. One type of these may be used alone, or two or more types may be mixed and used.

The above fatty acid metal salt lubricants include lithium salts, calcium salts, magnesium salts, and aluminum salts of the above fatty acid lubricants. One type of these may be used alone, or two or more types may be mixed and used.

As the above antistatic agents, fatty acid partial esters such as cationic, anionic, nonionic, and amphoteric glycerol fatty acid monoesters can be used.

Specifically, alkyl trimethylammonium salts, dialkyl dimethylammonium salts, benzalkonium salts, N,N-bis(2-hydroxyethyl)-N-(3-dodecyloxy-2-hydroxypropyl)methylammonium mesosulfate, (3-laurylamidopropyl)trimethylammonium methylsulfate, stearamidopropyl dimethyl-2-hydroxyethyl ammonium nitrate, stearamidopropyl dimethyl-2-hydroxyethyl ammonium phosphate, cationic polymers, alkyl sulfonates, alkyl benzene sulfonates, sodium alkyl diphenyl ether disulfonates, alkyl nitrates, alkyl phosphates, alkyl phosphate amine salts, stearic acid monoglycerides, pentaerythritol fatty acid esters, sorbitan monopalmitate, sorbitan monostearate, diglycerol fatty acid esters, alkyl diethanolamine, alkyl diethanolamine fatty acid monoesters, alkyl diethanolamides, polyoxyethylene dodecyl ethers, polyoxyethylene alkyl phenyl ethers, polyoxyethylene glycol monolaurate, polyoxyethylene alkylamine, polyoxyethylene alkylamide, polyether block copolymers, cetyl betaine, hydroxyethyl imidazoline sulfate, and the like. One type of these may be used alone, or two or more types may be mixed and used.

As the above fillers, talc, calcium carbonate, barium sulfate, carbon fibers, mica, wollastonite, whiskers, and the like can be used.

In the present embodiment, the styrene-based resin composition may contain optional additive components including the above additives, processing promoters, and other additives such as anti-blocking agents, coloring agents, anti-blooming agents, surface treatment agents, antimicrobial agents, and die-drool prevention agents (a die-drool prevention agent such as a monoester compound produced by reacting a silicone oil, a monoamide compound of a higher aliphatic carboxylic acid, and a higher aliphatic carboxylic acid with a univalent to trivalent alcoholic compound described in JP2009120717A). The total content of the optional additive components such as the additives and the processing promoters may be 0.05 mass % to 5 mass % in the styrene-based resin composition.

The styrene-based resin composition of the present embodiment may consist substantially only of the (A1) component, (B) component, catechol derivative, dimers and trimers, and optional additive components. The styrene-based resin composition may also consist only of the (A1) component, catechol derivative, dimers and trimers, and (B) component.

“Consisting substantially only of the (A1) component, (B) component, and optional additive components” means that 95 mass % to 100 mass % (preferably 98 mass % to 100 mass %) of the styrene-based resin composition is composed of the (A1) component, the (B) component, or the (A1) component, (B) component, and optional additive components.

The styrene-based resin composition of the present embodiment may contain unavoidable impurities other than the (A1) component, (B) component, and optional additive components, to the extent that the effects of the present disclosure are not impaired.

[Flame Retardant Styrene-Based Resin Composition]

The present disclosure relates to another aspect of the styrene-based resin composition that contains 77.0 mass % to 98.9 mass % of a styrene-based resin (A2), 1.0 mass % to 20.0 mass % of the phosphinic acid compound (C1), and 0.1 mass % to 3.0 mass % of the hindered amine compound (C2).

That is, when flame retardant effects are emphasized, the styrene-based resin composition of the present disclosure can be a frame-retardant styrene-based resin composition that uses the styrene-based resin (A2), instead of the styrene-based resin (A1), and contains the phosphinic acid compound (C1) and the hindered amine compound (C2) described above.

In the flame retardant styrene-based resin composition of the present embodiment, the styrene-based resin (A2) can be the same resin as the styrene-based resin (A1), but a catechol derivative, dimers of styrene-based monomer units, and trimers of the styrene-based monomer units may not be incorporated into the styrene-based resin (A2).

Therefore, the styrene-based resin (A2) that can be used in the present embodiment is a resin obtained by polymerizing the styrene-based monomer units and, if necessary, one or more types of monomer units and/or polymers selected from other vinyl monomer units and rubbery polymers (a) that can be copolymerized with the styrene-based monomer units. Specifically, there are, for example, but not limited to, polystyrene, rubber-modified styrene-based resins in which particles of the rubbery polymer (a) are dispersed in a polymer matrix, and styrene copolymer resins. Therefore, the styrene-based resin (A2) of the present disclosure contains the styrene-based monomer units as an essential component and, if necessary, another/other vinyl monomer unit/units (unsaturated carboxylic acid monomer unit/units, unsaturated carboxylic acid ester monomer unit/units) and/or rubbery polymer (a) monomer unit/units.

In the flame retardant styrene-based resin composition of the present embodiment, the styrene-based resin (A2) is preferably the styrene-based resin (A1). That is, in the present embodiment, the styrene-based monomer unit that is the repeating unit constituting the styrene-based resin (A2) is preferably a monovinylstyrene-based monomer unit. In addition, the styrene-based resin (A2) contains a cross-linkable aromatic vinyl compound (unit) such as an aromatic compound (unit) having two or more vinyl groups (e.g., divinylbenzene) preferably in 4.5 mass % or less, and more preferably in 3 mass % or less. This makes it easier to reduce the total content with dimers and trimers of the styrene-based monomer units.

The styrene-based resin (A2) that can be used in the present embodiment preferably contains 6 μg or less of a catechol derivative per gram of the styrene-based resin (A2). The styrene-based resin (A2) preferably contains dimers of the styrene-based monomer units, which are repeating units constituting the styrene-based resin (A1), and trimers of the styrene-based monomer units by a total content of 5000 or less per gram of the styrene-based resin (A1).

In a preferred aspect the frame-retardant styrene-based resin composition of the present embodiment, the frame-retardant styrene-based resin composition indispensably contains 77.0 mass % to 98.9 mass % of the styrene-based resin (A2), 1.0 mass % to 20.0 mass % of the phosphinic acid compound (C1), and 0.1 mass % to 3.0 mass % of the hindered amine compound (C2), and contains 6 μg or less of the catechol derivative in the styrene-based resin (A2) per gram of the styrene-based resin (A2), such that the total amount of the dimers of the styrene-based monomer units, which are the repeating units constituting the styrene-based resin (A2), and the trimers of the styrene-based monomer units contained in the styrene-based resin (A2) is 5000 μg or less per gram of the styrene-based resin (A1). The styrene-based resin composition has a dielectric constant of 3 or less and a dielectric loss tangent of 0.02 or less. The catechol derivative, the dimers of the styrene-based monomer units, and the trimers of the styrene-based monomer units are the same as the substances incorporated into the styrene-based resin (A1), and the contents can be used as a reference.

In the flame retardant styrene-based resin composition of the present embodiment, the content of the styrene-based resin (A2) is 77.0 mass % to 98.9 mass %, preferably 85 mass % to 97 mass %, and more preferably 90 mass % to 96 mass % relative to the total amount 100 mass % of the (A2) component, the (C1) component, and the (C2) component. By setting the content to 77.0 mass % or more, high heat resistance can be obtained. By setting the content to 98.9 mass % or less, high flame retardance can be obtained.

The phosphinic acid compound (C1) and the hindered amine compound (C2) that can be used in the flame retardant styrene-based resin composition of the present embodiment are the same as those described above <PHOSPHINIC ACID COMPOUND (C1)> and <HINDERED AMINE COMPOUND (C2)>, and the contents thereof can be used as a reference.

In the present embodiment, the content of the phosphinic acid compound (C1) is 1.0 mass % to 20.0 mass %, preferably 2.0 mass % to 15.0 mass %, and more preferably 3.0 mass % to 10.0 mass % relative to the total amount 100 mass % of the (A2) component, the (C1) component, and the (C2) component. By setting the content to 1.0 mass % or more, high flame retardance can be obtained as the frame-retardant styrene-based resin composition, and excellent color tone can be obtained. By setting the content to 20.0 mass % or less, the styrene-based resin composition with high heat resistance can be obtained.

In the present embodiment, the content of the hindered amine compound (C2) is 0.1 mass % to 3 mass %, preferably 0.3 mass % to 2.5 mass %, and more preferably 0.5 mass % to 2.0 mass % relative to the total amount 100 mass % of the (A2) component, the (C1) component, and the (C2) component. By setting the content to 0.1 mass % or more, high flame retardance can be obtained and gas generation can be suppressed, resulting in products with excellent molded appearance. By setting the content to 3.0 mass % or less, the color tone is excellent. The hindered amine compound (C2) is a well-known light stabilizer, and addition of the hindered amine compound (C2) can also impart light resistance. The hindered amine compound (C2) in the present embodiment is preferably a NOR-type hindered amine compound, because of high effects in suppressing gas generation. Furthermore, when the hindered amine compound (C2) and the phosphinic acid compound (C1) are used together, a high level of flame retardance can be achieved by synergistic effects.

The frame-retardant styrene-based resin composition of the present disclosure may be used as a flame retardant masterbatch, and include a flame retardant masterbatch and a composition containing the flame retardant masterbatch.

In addition to the above (A2) component, (C1) component, and (C2) component, the flame retardant styrene-based resin composition of the present embodiment may contain optional additive components such as conventionally known additives and processing promoters as necessary to the extent that the effects of the present invention are not impaired. The optional additive components that can be blended into flame retardant styrene-based resin composition are the same as those described above, so the above description is used as a reference. The total content of the optional additive components such as the additives and processing promoters may be 0.05 mass % to 5 mass % in the frame-retardant styrene-based resin composition.

The frame-retardant styrene-based resin composition of the present embodiment may consist substantially only of the (A2) component, (C1) component, (C2) component, and optional additive components. The frame-retardant styrene-based resin composition may also consist only of the (A2) component, (C1) component, and the (C2) component. “Consisting substantially only of the (A2) component, (C1) component, (C2) component, and optional additive components” means that 95 mass % to 100 mass % (preferably 98 mass % to 100 mass %) of the frame-retardant styrene-based resin composition is composed of the (A2) component, the (C1) component, the (C2) component, or the (A2) component, (C1) component, (C2) component, and optional additive components. The frame-retardant styrene-based resin composition of the present embodiment may contain unavoidable impurities other than the (A2) component, (C1) component, (C2) component, and optional additive components, to the extent that the effects of the present disclosure are not impaired.

[Method of Manufacturing Styrene-Based Resin Composition]

The styrene-based resin composition or frame-retardant styrene-based resin composition of the present embodiment can be produced by melting and kneading each component by any method. For example, a high-speed agitator such as a Henschel mixer, a batch type kneader such as a Banbury mixer, a uniaxial or biaxial continuous kneader, a roll mixer, or the like may be used alone or in combination. A heating temperature during kneading is usually selected in the range of 180° C. to 260° C.

[Patch Antenna]

The present disclosure is a patch antenna including: a patch substrate; a ground substrate provided at a distance from the patch substrate; and a dielectric layer sandwiched between the patch substrate and the ground substrate, wherein the dielectric layer is composed of a styrene-based resin composition containing a catechol derivative, a styrene-based resin (A1) having styrene-based monomer units as repeating units, dimers of the styrene-based monomer units, and trimers of the styrene-based monomer units, the catechol derivative is 6 μg or less per gram of the styrene-based resin (A1), and a total amount of the dimers of the styrene-based monomer units and the trimers of the styrene-based monomer units is 5000 μg or less per gram of the styrene-based resin (A1).

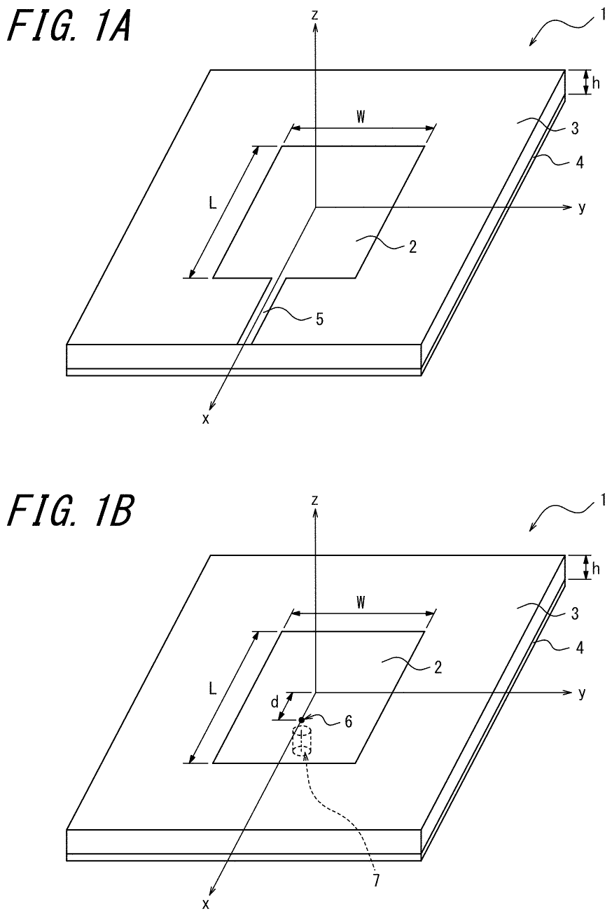

The configuration of the patch antenna of the present embodiment will be described below with reference to FIGS. 1A and 1B. Both patch antennas 1 illustrated in FIGS. 1A and 1B are laminated structures in which a ground substrate 4, a dielectric layer 3 having insulating properties, and a patch substrate 2 are stacked in this order. In FIGS. 1A and 1B, x-y-z represents Cartesian coordinate axes centered on the center of gravity of the patch substrate 2, provided for convenience of explanation. The direction outward from the patch substrate 2 is defined as a +z-axis direction, and the direction from the patch substrate 2 to the ground substrate 4 is defined as a −z-axis direction.

FIG. 1A illustrates an example of the patch antenna 1 using a microstrip line 5, as an example of the patch antennas of the present embodiment. The patch antenna 1 illustrated in FIG. 1A is provided with the dielectric layer 3, the rectangle-shaped patch substrate 2 formed in a first main surface (surface of the patch substrate 2 on the side of the +z-axis direction) of the dielectric layer 3, and the ground substrate 4 formed in a second main surface (surface of the patch substrate 2 on the side of the −z-axis direction) of the dielectric layer 3. The patch substrate 2 is electrically connected to the microstrip line 5, which is disposed on the same plane as the patch substrate 2 (in FIG. 1A, the patch substrate 2 and microstrip line 5 are directly connected). If necessary, a (pair of) cutouts parallel to a long axis direction of the microstrip line 5 may be provided at a junction between the patch substrate 2 and the microstrip line 5 to adjust the position of a tip portion of the microstrip line, which results in adjustment of impedance. When W and L represent the width and length of the patch substrate 2, respectively, the patch antenna 1 is driven as an open resonator that resonates at a frequency at which L is an integer multiple of a wavelength (λ)/2. In the patch antenna 1 illustrated in FIG. 1A is a planar antenna in which the patch substrate 2 formed on the dielectric layer 3 serves as a radiating element, and the microstrip line 5 serves as a power line for electrical connection to a transmitter and receiver (not illustrated). For example, when the dielectric layer 3 with a low dielectric constant is used and W and h are set to relatively large values with respect to the wavelength, the patch antenna 1 with increased radiation can be obtained.

FIG. 1B illustrates the patch antenna 1 that is powered from the back of the patch substrate 2, as an example of the patch antennas of the present embodiment. The patch antenna 1 illustrated in FIG. 1B is provided with the dielectric layer 3, the rectangle-shaped patch substrate 2 formed in a first main surface (surface of the patch substrate 2 on the side of the +z-axis direction) of the dielectric layer 3, and the ground substrate 4 formed in a second main surface (surface of the patch substrate 2 on the side of the −z-axis direction) of the dielectric layer 3. A The dielectric layer 3 has a through hole 7 formed through the dielectric layer 3. The through hole 7 extends from the back of the patch substrate 2 (surface of the patch substrate 2 on the side of the −z-axis direction) through the dielectric layer 3 and the ground substrate 4 in an approximately cylindrical shape. A projected position of the through hole with respect to the surface of the patch substrate 2 (surface of the patch substrate 2 on the side of the +z-axis direction) corresponds to a power supply point 6. In the configuration of the patch antenna 1, a coaxial line (such as an SMA connector illustrated by, for example, the straight dotted line in the drawing) is inserted into the through hole 7 and electrically connected to the patch substrate 2.

In FIG. 1B, the power supply point 6 is located at a distance d away from the center of gravity of the patch substrate 2. By setting the power supply point 6 at an appropriate position on the patch substrate 2, impedance matching can be obtained.

In the patch antennas 1 illustrated in FIGS. 1A and 1B, the rectangular shape is adopted as an example of the shape of the patch substrate 2. However, the shape of the patch substrate 2 is not particularly limited and may be circular, elliptical, or polygonal. For example, in the case of a hexagonal shape with one pair of diagonal corners of the patch substrate 2 notched, circularly polarized waves can be radiated.

When the patch antennas 1 illustrated in FIGS. 1A and 1B are fed at an appropriate position in the x-axis direction, a current standing wave has zero amplitude at both ends of the patch substrate 2 and maximum amplitude at the center of the patch substrate 2 in the x-axis direction. Therefore, due to the relationship between the current standing wave and a voltage standing wave, the voltage standing wave has maximum amplitude at both ends of the patch substrate 2 and zero amplitude at the center of the patch substrate 2 in the x-axis direction. As a result, a magnetic current caused by a fringing electric field generated at the periphery of the patch substrate 2 becomes a main radiation source of the antenna, and radiation intensity in the +z-axis direction becomes maximum.

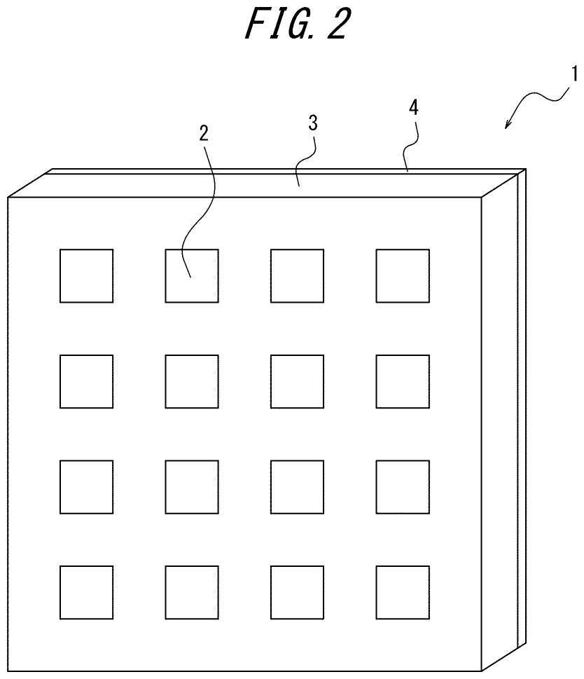

From the viewpoint of further enhancing the directivity in the +z-axis direction, the patch antenna 1 may be of a microarray method. For example, a patch antenna 1 illustrated in FIG. 2 is a laminated structure, as with the patch antennas 1 illustrated in FIGS. 1A and 1B, in which a ground substrate 4, a dielectric layer 3 having insulating properties, and a plurality of patch substrates 2 are stacked in this order. The patch antenna 1 illustrated in FIG. 2 is an antenna that is constituted of the plurality of patch substrates 2 arranged at appropriate intervals and a power circuit for exciting the plurality of patch substrates 2. Thereby, the directivity in the +z-axis direction can be further improved.

In a preferred aspect of the patch antenna 1 of the present embodiment, the average width W (mm) of the patch substrate 2 is preferably in the range of approximately 0.75 to 2.5 times the average length L (mm) of the patch substrate 2.

In the preferred aspect of the patch antenna 1 of the present embodiment, the average thickness h (mm) of the patch antenna 1 is preferably approximately 0.0025 to 0.0055 times a free space wavelength λ (mm) at an operating frequency.

The dielectric layer 3, the patch substrate 2, and the ground substrate 4, which are components of the patch antenna 1 of the present disclosure, will be hereinafter described.

<Dielectric Layer>

In the present embodiment, the dielectric layer 3 preferably has a dielectric loss tangent (tan δ) of 0.02 or less at 10 GHz. The relative dielectric constant of the dielectric layer 3 at 10 GHz is preferably 3 or less. By setting the dielectric loss tangent of the dielectric layer 3 at 10 GHz to 0.02 or less, dielectric loss can be reduced in a high-frequency range such as above 5 GHz.

Setting the relative dielectric constant of the dielectric layer 3 at 10 GHz to 3 or less can also reduce the dielectric loss in the high-frequency range. The dielectric loss tangent of the dielectric layer 3 at 10 GHz is more preferably 0.02 or less, and even more preferably 0.01 or less. The relative dielectric constant of the dielectric layer 3 is more preferably 3 or less, and even more preferably 2.5 or less.

The dielectric layer 3 of the present embodiment contains the styrene-based resin composition described above. More specifically, the dielectric layer 3 is formed of the styrene-based resin composition. When the amounts of the catechol derivative and the dimers and trimers of the styrene-based monomer units are within the above range, oxidative degradation of the dielectric can be prevented. Therefore, problems due to yellowing, such as deterioration in the dielectric loss tangent, product appearance, and material recycling, can be prevented. In high-frequency applications, temperature in usage environment is high, and styrene-based resin is susceptible to yellowing and degradation. Therefore, by keeping the amount of 4-t-butylcatechol, styrene dimers, and styrene trimers in the styrene-based resin composition at predetermined levels or less, the performance of a low dielectric constant and a low dielectric loss tangent less deteriorates.

The low dielectric constant in this specification refers to a dielectric constant of 3 or less, and the low dielectric loss tangent refers to a dielectric loss tangent of 0.02 or less.

In the present embodiment, by using the styrene-based resin composition in the dielectric layer 3, the transmission loss of the patch antenna 1 at 10 GHz can be reduced. More specifically, the transmission loss can be reduced to 1 dB/cm or less. Therefore, the quality and characteristics such as strength of high-frequency signals, especially high-frequency signals above 5 GHz, and even high-frequency signals of 10 GHz or more are maintained, the dielectric layer 3 and the patch antenna 1 that are suitable for high-frequency devices handling such high-frequency signals can be provided. In other words, the characteristics and quality of the high-frequency devices that handle such high-frequency signals can be improved. The transmission loss of the patch antenna 1 at 10 GHz is more preferably 0.5 dB/cm or less.

<Patch Substrate and Ground Substrate>

In the present embodiment, the patch substrate 2 and the ground substrate 4 are layers formed of conductors. For example, the thicknesses of the patch substrate 2 and ground substrate 4 are, for example, of the order of 0.1 μm to 50 μm. The conductors forming the patch substrate 2 and the ground substrate 4 are not particularly limited, but are preferably, for example, metals such as copper, gold, silver, aluminum, titanium, chromium, molybdenum, tungsten, platinum, or nickel, or alloys or metal compounds containing at least one of these metals. The structure of the patch substrate 2 and ground substrate 4 is not limited to a one-layer structure, but can also be a structure with multiple layers, such as a laminated structure with a titanium layer and a copper layer. A method of forming the patch substrate 2 and ground substrate 4 is not particularly limited, and various known formation methods such as bonding with known adhesives, printing using conductor paste, dipping, plating, vapor deposition, sputtering, and hot-pressing can be applied.

<Microstrip Line>

In the present embodiment, the microstrip line 5 is preferably a layer formed of a conductor. The same material as the patch substrate 2 and ground substrate 4 described above can be applied to form the microstrip line 5. The higher the relative dielectric constant of the dielectric layer 3, the more strongly an electromagnetic field generated by the patch substrate 2 or the power line (for example, microstrip line 5) tends to be constrained inside the dielectric layer 3. Therefore, the dielectric layer 3 with a low dielectric constant is preferred for the patch substrate 2. On the other hand, the dielectric layer 3 with a high dielectric constant is preferred for the power line.

<Preferred Aspect>

The present embodiment is preferably a styrene-based resin composition for a device component that communicates by electromagnetic waves, and the styrene-based resin composition contains a styrene-based resin (A1) having styrene-based monomer units as repeating units,

the styrene-based resin (A1) is a rubber-modified styrene-based resin in which particles of a rubbery polymer (a) are dispersed in a polymer matrix having monovinylstyrene-based monomer units as repeating units, or a styrene copolymer resin containing the styrene-based monomer units and unsaturated carboxylic acid monomer units and/or unsaturated carboxylic acid ester monomer units, and contains 0 mass % or more and 4.5 mass % or less of an aromatic vinyl compound having two or more vinyl groups,

a catechol derivative contained in the styrene-based resin (A1) is 6 μg or less per gram of the styrene-based resin (A1), and the total amount of dimers of the styrene-based monomer units and trimers of the styrene-based monomer units contained in the styrene-based resin (A1) is 5000 μg or less per gram of the styrene-based resin (A1), and

the styrene-based resin composition has a dielectric constant of 3 or less and a dielectric loss tangent of 0.02 or less.

Thereby, the resin composition that maintains a low dielectric loss tangent after holding at high temperature, has little change in yellowness, and has excellent adhesive strength to metallic materials can be provided. Therefore, the styrene-based resin composition of the present embodiment is preferred for use in electronic devices for so-called high-frequency applications that communicate by electromagnetic waves, rather than materials used for optical applications such as light guide plates.

The styrene-based resin (A1) is preferably a styrene copolymer resin, and a copolymer that contains, 98 mass % or less of the styrene-based monomer units, 0 mass % to 16 mass % of the unsaturated carboxylic acid monomer units, and 0 mass % to 16 mass % of the unsaturated carboxylic acid ester monomer units relative to 100 mass % of the styrene copolymer resin.

<Preferred Use>

A preferred aspect of the styrene-based resin composition of the present embodiment is a device component that communicates by electromagnetic waves or a molded body for the device component.

Specifically, the present embodiment is preferably a device component that communicates by electromagnetic waves or a molded body for the device component, and the device component or the molded body includes, as a component, a styrene-based resin composition containing a styrene-based resin (A1) having styrene-based monomer units as repeating units,

the styrene-based resin (A1) is a rubber-modified styrene-based resin in which particles of a rubbery polymer (a) are dispersed in a polymer matrix having monovinylstyrene-based monomer units as repeating units, or a styrene copolymer resin containing the styrene-based monomer units and unsaturated carboxylic acid monomer units and/or unsaturated carboxylic acid ester monomer units, and contains 0 mass % or more and 4.5 mass % or less of an aromatic vinyl compound having two or more vinyl groups,

a catechol derivative contained in the styrene-based resin (A1) is 6 μg or less per gram of the styrene-based resin (A1), and the total amount of dimers of the styrene-based monomer units and trimers of the styrene-based monomer units contained in the styrene-based resin (A1) is 5000 μg or less per gram of the styrene-based resin (A1), and

a dielectric constant is 3 or less, and a dielectric loss tangent is 0.02 or less.

Thereby, the device component that maintains a low dielectric loss tangent after holding at high temperature, has little change in yellowness, and has excellent adhesive strength to metallic materials can be provided. Therefore, the device component of the present embodiment or the molded body of the device component is preferred for use in electronic devices for so-called high-frequency applications that communicate by electromagnetic waves, rather than materials used for optical applications such as light guide plates.

The styrene-based resin (A1) is preferably a styrene copolymer resin, and a copolymer that contains, 98 mass % or less of the styrene-based monomer units, 0 mass % to 16 mass % of the unsaturated carboxylic acid monomer units, and 0 mass % to 16 mass % of the unsaturated carboxylic acid ester monomer units relative to 100 mass % of the styrene copolymer resin.

In the present embodiment, when high mechanical strength properties are required for use in housing materials for electronic devices, it is preferable that the rubber-modified styrene-based resin is used as the styrene-based resin (A1). On the other hand, when high-frequency applications are emphasized for use in the above-described patch antennas and the like, the styrene copolymer resin that exhibits excellent heat resistance is preferably used.

[Physical Properties of Styrene-Based Resin Composition or Dielectric Layer]

<Dielectric Constant and Dielectric Loss Tangent>

The dielectric constant of the styrene-based resin composition or dielectric layer of the present embodiment is preferably 3 or less, and more preferably 2.5 or less. The dielectric loss tangent of the styrene-based resin composition or dielectric layer is 0.02 or less, and more preferably 0.01 or less. When the dielectric constant is more than 3 and the dielectric loss tangent is more than 0.02, dielectric loss increases at high frequencies of 0.3 GHz or more, thus resulting in defects in the product.

In the present disclosure, the dielectric constant and the dielectric loss tangent are values measured at 10 GHz in accordance with JIS C2138.

<Yellow Index>

The yellow index of the styrene-based resin composition or dielectric layer of the present embodiment is preferably 20 or less, and more preferably 10 or less. When the yellow index is more than 20, coloring and other defects may occur. In the present disclosure, the yellow index (YI) is a value measured in accordance with JIS K7105.

The yellow index of the frame-retardant styrene-based resin composition of the present embodiment is preferably 5 or less, and more preferably 3 or less. When the yellow index is more than 5, there is concern that the frame-retardant styrene-based resin composition cannot be used for optical applications.

<Flame Retardance>

The flame retardance of the styrene-based resin composition or frame-retardant styrene-based resin composition of the present embodiment, depending on application, such as electrical product-related applications, may be within the standard of the UL94 vertical flame test (UL94-V test), i.e., V-0 to V-2 flame retardant grades. In addition, in the UL94 horizontal flame test (UL94-HB test), a burning rate is preferably 75 mm/min or less, which is within the HB standard, and in consideration of the automotive flame retardant standard (FMVSS302) and other standards, the burning rate is preferably 85 mm/min or less. In the present disclosure, flame retardance can be evaluated by the method described in “EXAMPLES” below.

<Vicat Softening Temperature>

The Vicat softening temperature of the frame-retardant styrene-based resin composition of the present embodiment is preferably 86° C. or more, and more preferably 88° C. or more. When the Vicat softening temperature is less than 86° C., the temperature rises during use and the product may be deformed. In the present disclosure, the Vicat softening temperature is a value measured in accordance with ISO 306, using a load of 49N and a temperature increase rate of 50° C./hour.

[Molded Body]

The styrene-based resin composition or flame retardant styrene-based resin composition of the present embodiment can be made into a molded body by the above melt-mixing and molding machine, or using obtained pellets of the styrene-based resin composition or the flame retardant styrene-based resin composition as a raw material, by injection molding, injection compression molding, extrusion molding, blow molding, press molding, vacuum molding, foam molding, or the like. Similarly, the dielectric layer 3 of the present embodiment can be produced by the above melt-mixing and molding machine by injection molding, injection compression molding, extrusion molding, blow molding, press molding, vacuum molding, foam molding, or the like.

A molded product or molded body, preferably an injection molded product or injection molded body (including injection compression), containing the styrene-based resin composition of the present embodiment, or the dielectric layer 3 relates to a component, housing, or housing component of a device that communicates by electromagnetic waves having a frequency of 0.3 to 300 GHz. In particular, the molded product or molded body containing the styrene-based resin composition of the present embodiment, or the dielectric layer 3 can be used in a product selected from the group of transmitting and receiving devices, cellular phones, tablets, laptops, navigation devices, surveillance cameras, photography cameras, sensors, diving computers, audio units, remote controls, speakers, headphones, radios, televisions, lighting devices, home appliances, kitchen appliances, door or gate openers, operating devices for vehicle central locks, keys for keyless cars, temperature measuring or temperature display devices, components of measurement and control devices, and housings or housing components.

A molded product, preferably an injection molded product (including injection compression), containing the flame retardant styrene-based resin composition of the present embodiment in housings, various components, foam insulation materials, insulating films, and the like for OA equipment, home appliances, and electrical and electronic equipment such as copiers, fax machines, televisions, radios, tape recorders, video cassette recorders, personal computers, printers, telephone sets, information terminals, refrigerators, and microwave ovens.

### EXAMPLES

The embodiment of the present disclosure will be more concretely described below based on Examples and Comparative Examples, but the disclosure is not limited in any way by these Examples.

[Measurement and Evaluation Methods]

The measurement and evaluation of the physical properties of resin compositions obtained in each of the Examples and Comparative Examples were based on the following methods.

(1) Measurement of Amounts of Dimers and Trimers of Styrene-Based Monomer Units

Instrument: Agilent 6850 series GC system

Sample: After dissolving 1 g of a resin composition in 10 ml of MEK, 3 ml of methanol was added to precipitate a polymer and the concentration of components in solution was measured.

Column: Agilent 19091Z-413E

Entrance temperature: 250° C.

Detector temperature: 280° C.

(2) Measurement of Amount of 4-t-Butylcatechol

Instrument: Agilent 6890

Sample: After dissolving 1 g of a resin composition in 50 ml of chloroform, trimethylsilyl derivatization treatment was performed using BSTFA (N,O-bis(trimethylsilyl)trifluoroacetamide).

Column: DB-1 (0.25 mm i.d.×30 m)

Liquid phase thickness: 0.25 mm

Column Temperature: 40° C. (hold for 5 min) (temperature increase at 20° C./min) 320° C. (hold for 6 min): Total 25 min

Inlet temperature: 320° C.

Injection method: Split method (split ratio 1:5)

Sample volume: 2 μl

MS instrument: Agilent MSD5973

Ion source temperature: 230° C.

Interface temperature: 320° C.

Ionization method: Electron ionization (EI) method

Measurement method: SCAN method (scan range m/Z 10 to 800)

(3) Content of Rubbery Polymer (a) in Rubber-Modified Styrene-Based Resin:

Based on a bonding mode of butadiene segments, pyrolysis gas chromatography was measured and the content of a rubbery polymer (a) was calculated from the amount of the butadiene segments. The unit is wt %.

(4) Calculation Method for Content of Styrene Monomer Units, Methacrylic Acid Monomer Units, and Methyl Methacrylate Monomer Units in Styrene Copolymer Resin

A resin composition was quantified from an integral ratio of spectra measured by a proton nuclear magnetic resonance (¹H-NMR) measuring machine.
Sample Preparation: 30 mg of resin pellets was heated and melt in d₆-DMSO 0.75 mL at 60° C. for 4 to 6 hours
Measuring instrument: JNM ECA-500 produced by JEOL Ltd.
Measurement conditions: 25° C., observation nucleus ¹H, 64 times integration, 11 seconds repetition time

(Attribution of Spectra)

For the attribution of spectra measured in dimethyl sulfoxide heavy solvent, a peak at 0.5 ppm to 1.5 ppm is attributed to hydrogen of α-methyl groups of methacrylic acid, methyl methacrylate, and six-membered ring acid anhydride, a peak at 1.6 ppm to 2.1 ppm is attributed to hydrogen of a methylene group of a polymer main chain, and a peak at 3.5 ppm is attributed to hydrogen of carboxylic acid ester (—COOCH₃) of methyl methacrylate, and a peak at 12.4 ppm is attributed to hydrogen of carboxylic acid of methacrylic acid. A peak at 6.5 ppm to 7.5 ppm is attributed to hydrogen of an aromatic ring of styrene. Due to a low content of six-membered ring acid anhydride in resin of the Examples and Comparative Examples, quantification is usually difficult with this measurement method.

(5) Dielectric Constant and Dielectric Loss Tangent

The dielectric properties (dielectric constant and dielectric loss tangent) of styrene-based resin compositions produced in Examples 1 to 24 and Comparative Examples 1 to 11 were measured in accordance with JIS C2138 at 10 GHz by the PNA-L network analyzer N5230A (made by Agilent Technologies, Inc.) (200° C., 49 N load). The dielectric loss tangent was also measured after the styrene-based resin compositions were exposed to an oven at 80° C. for 500 hours.

(6) Yellow Index (YI)

In accordance with JIS K7105, the yellow index YI (at room temperature 25° C.) of the styrene-based resin compositions or specimens (a) produced by the method described below was measured by a color difference turbidity analyzer COH300A (tradename) produced by Nihon Denshoku Industries Co., Ltd. The yellow index YI (at 80° C.) after exposure to an oven at 80° C. for 500 hours was also measured, and the ΔYI was calculated by subtracting the value of YI (at room temperature 25° C.) from the value of YI (at 80° C.).

The yellow index YI (at room temperature 25° C.) of the specimens (a) is preferably 5 or less, considering the purpose of color adjustment.

(7) Evaluation of Flame Retardance

(7-1) Evaluation of Flame Retardant Grade

Using the specimens (a) (size: 127 mm×12.7 mm, thickness: 1.5 mm) or specimens (b) (size: 127 mm×12.7 mm, thickness: 0.8 mm) produced by the method described below, flame retardance was evaluated by the method in accordance with the UL94 vertical flame test (UL94-V test) with 50 W test flame.

The above specimens (a) or (b) were subjected to flame of gas burners to evaluate the degree of flammability.

Flame retardant grades indicate classes of flame retardance classified by the UL94-V test. The test was performed on five sticks of each specimen and judgment was made. A classification method is outlined below.

V-0: Total burning time of the five sticks of 50 seconds or less, maximum burning time of 10 seconds or less, no cotton ignition by drips of particles

V-1: Total burning time of the five sticks of 250 seconds or less, maximum burning time of 30 seconds or less, no cotton ignition by drips of particles

V-2: Total burning time of five sticks of 250 seconds or less, maximum burning time of 30 seconds or less, cotton ignition by drips of particles

Not V: Out of the standards of UL94

The measurement of the burning time was evaluated as the time from a first flame contact to extinguishing the flame in the UL94-V test, and five sets were performed (two flame contacts per set).

For Examples 25 to 33, in which the specimens (b) were prepared, the first burning time for each set is listed in Tables 7 and Table 9, and variations in flammability was evaluated by calculating an average deviation of the first burn time for each set.

(7-2) Burning Rate

As in the evaluation of flammability in above (7-1), a burning rate (mm/min) was measured by the UL94 horizontal flame test using three of each of the specimens (a) (size: 127 mm×12.7 mm, thickness: 1.5 mm) produced by the methods described in Examples 1 to 24 and Comparative Examples 1 to 11 below and specimens (b) (size: 127 mm×12.7 mm, thickness: 0.8 mm) produced by the method described in Examples 25 to 33 and Comparative Examples 12 to 20 below.

(8) Evaluation of Heat Resistance

Heat resistance was evaluated by Vicat softening point. In accordance with ISO 306, the Vicat softening temperature (° C.) of the resin composition was measured. A load was 49 N, and a heating rate was 50° C./hour.

(9) Evaluation of 90° Copper Foil Peel Strength (Minimum Copper Foil Adhesion)

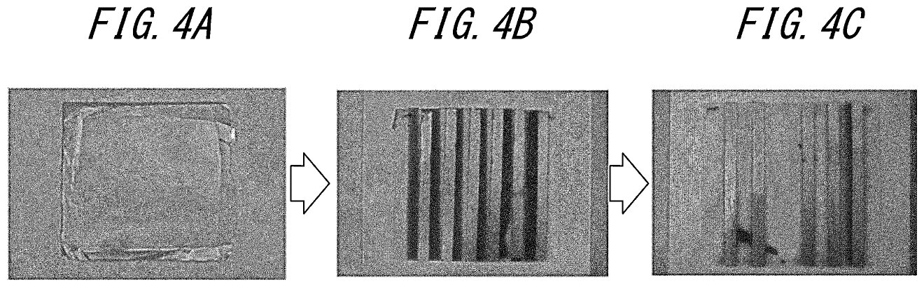

To resin sheets 130 mm×130 mm consisting of the styrene-based resin compositions of Examples 1 to 24 and Comparative Examples 1 to 11 described below, copper foil, which has the same size as the resin sheets and a thickness of 35 μm, was bonded by heat pressing at 200° C. (see FIG. 4A), and then the copper foil was etched with ferric chloride solution (see FIG. 4B). The peel strength of the copper foil was measured (see FIG. 4C) in accordance with JIS K 6854-1.

The measurement conditions are as follows.

Test speed: 50 mm/min

Specimen width: 10 (mm)

Number of measurements: n=5

Measurement environment: 23° C.±2° C., 50% RH±5% RH

Measuring device: Universal material testing machine, Model 59R5582 (made by Instron)

In the Examples, minimum copper foil adhesion, which is the value of the 90° copper foil peel strength, was defined as a minimum value of load applied within the range of a peel length of 20 to 100 mm. For example, when an experimental result of the 90° copper foil peel strength as indicated in FIGS. 4A to 4C was obtained, a peak of A was evaluated as the minimum copper foil adhesion.

(10) Evaluation of Adhesion

Flexible double-sided metallic laminated plates made by the method described below were exposed to a temperature of 80° C. and an atmosphere of 85% humidity for 500 hours, and then adhesion was measured in accordance with JIS K5600-5-6 (cross-cut method). Test results were evaluated by numbers from 0 (good) to 5 (poor) according to peeling conditions in the form of dices in accordance with JIS K5600-5-6 (cross-cut method).

(11) Evaluation of Transmission Loss (dB/Mm)

A microstrip line method with impedance Z=50Ω was used to measure transmission loss of the dielectric layer. The microstrip line method has been widely employed to measure transmission loss, because samples are easily produced and have structures suitable for mounting surface-mounted components.

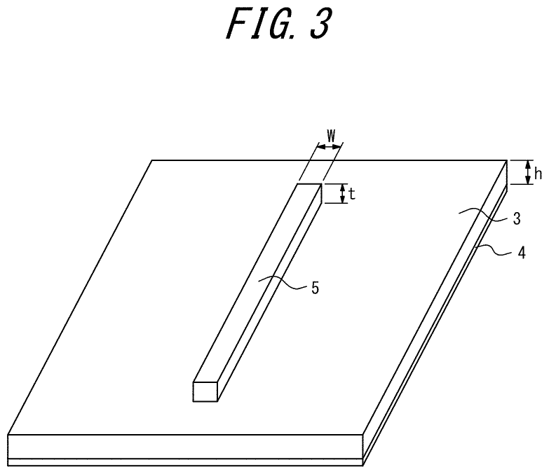

FIG. 3 is a perspective view of a sample produced by the microstrip line method. As illustrated in FIG. 3, the sample is a laminated structure that is constituted of a dielectric layer 3 made of a styrene-based resin composition, a copper plating layer of a thickness t and a width W provided on one side of the dielectric layer 3 as a microstrip line 5, and a copper plating layer provided and uniformly bonded on the other side of the dielectric layer 3 as a ground substrate 4. The sample corresponds to a flexible double-sided metal laminated plate described later.

Transmission loss was measured by the microstrip line method by measuring an initial transmission amount (transmission amount (dB) before exposure to an oven at 80° C. for 500 hours) and a transmission amount after the load test (transmission amount (dB) after exposure to the oven at 80° C. for 500 hours), and dividing the absolute value of each transmission amount by the line length (75 mm) of the microstrip line 5.

Specifically, for the flexible double-sided metal laminated plate (sample (A)) before the exposure to the oven at 80° C. for 500 hours and the flexible double-sided metal laminated plate (sample (B)) after the exposure to the oven at 80° C. for 500 hours, both ends of the microstrip line 5 and the ground substrate 4 were connected to a measuring device, and then the transmission of incident waves on the microstrip line 5 was measured (at a temperature of 23° C. and a humidity of 50% RH). The state adjustment of the initial transmission amount at 10 GHz and the transmission amount after loading was also performed.

The measuring equipment used for this measurement is as follows:

Measuring equipment: E8363B (Agilent Technologies Inc.)
Measurement frequency: 10 MHz to 40 GHz

The initial transmission amount and the transmission amount after the load test were all measured under the same conditions except for the conditions described above. The closer the transmission amount after the load test is to the initial transmission amount, the better the durability.

(12) Evaluation of Molded Appearance

For evaluation of molded appearance, the surface appearance of the specimens (a) produced by the method described in Examples 25 to 33 below was observed and evaluated according to the following evaluation criteria, and the specimens without silver streaks or fogging were evaluated as “good”. An evaluation method for the occurrence of “silver streaks or fogging” in the Examples was based on whether the silver streaks or fogging could be visually confirmed on a plate with a thickness of 3 mm molded by an injection molding machine, and an observation result was evaluated based on the following criteria. The plate with a thickness of 3 mm that was injection molded by an injection molding machine (EC60N Toshiba Machine Co., Ltd.) at a cylinder temperature of 200° C. and a mold temperature of 40° C. was used.

Silver Streaks Evaluation Criteria

Good: no silver streaks occurred.

Poor: silver streaks occurred in one or more molded bodies.

Fogging Evaluation Criteria

Good: no fogging occurred.

Poor: fogging occurred in one or more molded bodies.

(13) Evaluation of Vicat Softening Temperature

For specimens (a) produced by the method described in Examples 25 to 33 below, the Vicat softening temperature was measured in accordance with ISO 306 under a load of 49 N and a heating rate of 50° C./hour.

[Raw Materials]

Materials (styrene-based resin (A1), styrene-based resin (A2), flame retardant (B), additives, and the like) used in the Examples are as follows:

[Styrene-Based Resin (A1)]

In Examples 1 to 24 and Comparative Examples 1 to 11, GPPS-A, GPPS-B, GPPS-B, HIPS-A, HIPS-B, and styrene copolymers (a) to (e) were used the styrene-based resin (A1).

<GPP-A>

A polymerization solution purified by distillation in which 0.05 wt % of 1-1-bis(t-butylperoxy)cyclohexane was added to 100 parts by weight of a mixture of 85 wt % of styrene and 15 wt % of ethylbenzene was continuously charged into a 5.4-liter fully mixed reactor at 0.70 liters/hr, and a temperature was adjusted to 101° C. Subsequently, the polymerization solution was continuously fed into a 3.0-liter laminar flow reactor, which is equipped with a stirrer and capable of controlling temperature in three zones. The temperature of the laminar flow reactor was adjusted to 113° C./121° C./128° C. The obtained polymerization solution was continuously fed to a two-stage vented devolatilization extruder at an extruder temperature of 225° C. and a vacuum of 15 torr in the first and second vent stages to remove unreacted monomers and solvent, and then pelletized in the extruder to obtain the GPPS-A as the styrene-based resin (A1). 4-t-butyl catechol obtained together with the GPPS-A was 1.5 μg/g, and the total amount of styrene dimers and styrene trimers was 4530 μg/g. Each of the content of 4-t-butyl catechol and the total amount of the styrene dimers and styrene trimers indicates a content relative to 1 g of the GPPS-A.

<GPPS-B>

The GPPS-B was prepared as the styrene-based resin (A1) in the same manner as the GPPS-A, except that a part of the polymerization solution of the styrene-based resin was used without purification by distillation. 4-t-butyl catechol obtained together with the GPPS-B was 1.8 μg/g, and the total amount of dimers of 4-t-butyl catechol and trimers of 4-t-butyl catechol was 5880 μg/g. Each of the content of 4-t-butyl catechol and the total amount of the styrene dimers and styrene trimers indicates a content relative to 1 g of the GPPS-B.

<HIPS-A>

A raw material solution purified by distillation in which 13 parts of ethylbenzene, 0.03 parts of 1,1′-bis(t-butylperoxy)cyclohexane, 0.01 parts of di-t-butyl peroxide, 0.05 parts of n-dodecyl mercaptan, and 0.1 parts of octadecyl-3-(3,5-di-t-butyl-4-hydroxyphenyl)propionate as an antioxidant were added to a solution, in which 5 parts of high-cis polybutadiene rubber with a Mooney viscosity of 40 and 135 centipoise, which is the viscosity of a 5% styrene solution viscosity, were dissolved in 82.3 parts of styrene, was continuously charged into a 6-liter tank type first reactor with a stirrer at 2 liters/Hr, and temperature was adjusted such that solids concentration at an outlet of the first reactor became 35%, to complete phase conversion and form particles. The stirring speed of the first reactor at this time was set to 90 revolutions/minute. Further, polymerization was continued in a 6-liter tank type second reactor with a stirrer and in a third reactor of the same type and capacity. The tank temperature was adjusted such that the solid concentrations at outlets of the second and third reactors became 55% to 60%, and 68% to 73%, respectively. Then, the solution was fed to a vacuum devolatilization device at a temperature of 230° C. to remove unreacted styrene monomer units and solvent, and then pelletized in an extruder to obtain the HIPS-A as the styrene-based resin (A1). 4-t-butyl catechol obtained together with the HIPS-A was 1.1 μg/g, and the total amount of styrene dimers and styrene trimers was 2840 μg/g. Each of the content of 4-t-butyl catechol and the total amount of the styrene dimers and styrene trimers indicates a content relative to 1 g of the HIPS-A.

<HIPS-B>

A styrene-based resin composition was prepared in the same manner as the HIPS-A, except that a part of the polymerization solution of the styrene-based resin was used without purification by distillation. 4-t-butyl catechol obtained together with the HIPS-B was 1.7 μg/g, and the total amount of dimers and trimers was 5380 μg/g. Each of the content of 4-t-butyl catechol and the total amount of the styrene dimers and styrene trimers indicates a content relative to 1 g of the HIPS-B.

<Styrene Copolymer Resin>

—Styrene Copolymer (a)—

A polymerization raw material solution purified by distillation composed of 71.3 parts by mass of styrene (ST), 7.3 parts by mass of methacrylic acid (MAA), 6.4 parts by mass of methyl methacrylate (MMA), 15.0 parts by mass of ethyl benzene, and 0.025 parts by mass of 1,1-bis(t-butylperoxy)cyclohexane was continuously and subsequently fed at a rate of 1.1 liters/hour into a 4-liter fully mixed reactor, then into a polymerization device constituted of a 2-liter laminar flow reactor, and then into a devolatilizer connected to a single screw extruder for removing unreacted monomers, polymerization solvent, and other volatile matter, in order to prepare a resin.

Polymerization reaction conditions during the polymerization process were as follows: the polymerization temperature of the fully mixed reactor was 122° C., and the polymerization temperature of the laminar flow reactor was 120° C. to 142° C. The devolatilized unreacted gas was condensed in a condenser through a refrigerant at −5° C. and collected as unreacted liquid.

The final polymerization solution was dried at 215° C. under reduced pressure of 2.5 kPa for 30 minutes, then pelletized in an extruder to obtain the styrene copolymer (a) (also referred to as copolymer (a); The same applies to the other copolymers.) A styrene copolymer resin content in the final polymerization solution was 65.6 mass %, as measured by the formula of [(sample mass after drying/sample mass before drying)×100%]. The weight average molecular weight of the styrene copolymer (a) was 214,000 (214 thousands).

4-t-butyl catechol obtained together with the styrene copolymer (a) was 0.6 μg/g, and the total amount of styrene dimers and styrene trimers was 3720 μg/g. Each of the content of 4-t-butyl catechol and the total amount of the styrene dimers and styrene trimers indicates a content relative to 1 g of the styrene copolymer (a).

The composition ratio of the styrene copolymer (a) was 82.3 mass % of styrene monomer units, 9.8 mass % of methacrylic acid monomer units, and 7.9 mass % of methyl methacrylate monomer units. The composition of the styrene copolymer (a) was determined from the integral ratio of spectra measured by a proton nuclear magnetic resonance (¹H-NMR) measuring machine as follows:
Sample Preparation: 30 mg of resin pellets was heated and dissolved in 0.75 mL of d₆-DMSO at 60° C. for 4 to 6 hours.
Measuring instrument: JNM ECA-500 produced by JEOL Ltd.
Measurement conditions: 25° C., observation nucleus ¹H, 64 times integration, 11 seconds repetition time

For the attribution of spectra measured in dimethyl sulfoxide heavy solvent, a peak at 0.5 ppm to 1.5 ppm is attributed to hydrogen of α-methyl groups of methacrylic acid, methyl methacrylate, and six-membered ring acid anhydride, a peak at 1.6 ppm to 2.1 ppm is attributed to hydrogen of a methylene group of a polymer main chain, and a peak at 3.5 ppm is attributed to hydrogen of carboxylic acid ester (—COOCH₃) of methyl methacrylate, and a peak at 12.4 ppm is attributed to hydrogen of carboxylic acid of methacrylic acid. A peak at 6.5 ppm to 7.5 ppm is attributed to hydrogen of an aromatic ring of styrene. Due to a low content of six-membered ring acid anhydride in resin of the Examples and Comparative Examples, quantification is usually difficult with this measurement method.

<Styrene Copolymer (b)>

The styrene copolymer (b) was produced in the same manner as the above styrene copolymer (a) by adjusting the compound ratio of styrene (ST), methacrylic acid (MAA), and methyl methacrylate (MMA), polymerization temperature conditions, and other factors so as to achieve the composition ratio in Table 1 below.

—Styrene Copolymer (c)—

The styrene copolymer (c) was produced in the same manner as the above styrene copolymer (a) by adjusting the compound ratio of styrene (ST), methacrylic acid (MAA), and methyl methacrylate (MMA), polymerization temperature conditions, and other factors so as to achieve the composition ratio in Table 1 below.

—Styrene Copolymer (d)—

The styrene copolymer (d) was produced in the same manner as the above styrene copolymer (a) by adjusting the compound ratio of styrene (ST), methacrylic acid (MAA), and methyl methacrylate (MMA), polymerization temperature conditions, and other factors so as to achieve the composition ratio in Table 1 below.

—Styrene Copolymer (e)—

The styrene copolymer (e) was produced in the same manner as the above styrene copolymer (a) by adjusting the compound ratio of styrene (ST), methacrylic acid (MAA), and methyl methacrylate (MMA), polymerization temperature conditions, and other factors so as to achieve the composition ratio in Table 1 below.

The composition ratios of the styrene copolymers (a) to (e) obtained above are listed below in Table 1.

TABLE 1

| | | | Copolymer (a) | Copolymer (b) | Copolymer (c) | Copolymer (d) | Copolymer (e) |
|---|---|---|---|---|---|---|---|
| Composition | ST monomer units | mass % | 82.3 | 91.8 | 74.7 | 83.8 | 94 |
| of resin | MAA monomer units | mass % | 9.8 | 8.2 | 10.1 | 16.2 | 0.0 |
| | MMA monomer units | mass % | 7.9 | 0 | 15.2 | 0 | 0 |
| | Divinylbenzene monomer units | mass % | 0 | 0 | 0 | 0 | 6 |

[Styrene-Based Resin (A2)]

In Examples 25 to 33 and Comparative Examples 12 to 20, the following HIPS, GPPS, the styrene copolymer (a) were used.

<HIPS>

A rubber-modified styrene-based resin, which is high impact polystyrene (HIPS) with an MFR of 7.0, was used. The HIPS used polybutadiene as a rubbery polymer, and the content of the rubbery polymer was 8.6 mass %. The average particle diameter of the high impact polystyrene (HIPS) was 1.5 μm.

<GPPS>

Polystyrene (GPPS; G9401 produced by PS Japan Corporation) with an MFR of 2.2 was used.

<Styrene Copolymer Resin>

The styrene copolymer (a) described above was used as a styrene-based resin (A2).

[Flame Retardant (B)]

Phosphonic Acid Ester Compound:

[Non Nen 73 produced by Marubishi Oil Chemical Corporation, melting point 100° C., phosphorus content 10 mass %]

Phosphate Ester (Compound (II-2)):

resorcinol bis-dixylenyl phosphate [PX-200 produced by Daihachi Chemical Industry Co., Ltd., melting point 92° C., phosphorus content 9.0 Melting point 92° C., phosphorus content 9.0 mass %, condensation type]

Phosphinic Acid Compound (C1-1):

(also referred to as phosphinic acid-A in the tables) [HCA produced by Sanko Inc., 9,10-dihydro-9-oxa-10-phosphaphenanthrene-10-oxide]

Phosphinic acid compound (C1-2):

(also referred to as phosphinic acid-B in the tables) [BCA produced by Sanko Inc., 10-benzyl-9,10-dihydro-9-oxa-10-phosphaphenanthrene-10-oxide]

Hindered Amine Compound (C2-1):

(also referred to as HALS-A in the tables) [FlamestabNOR116FF, NOR polymer type, produced by BASF]

Hindered Amine Compounds (C2-2):

(also referred to as HALS-B in the tables) [Adekastab, LA-81, NOR type, produced by ADEKA Corporation]

Hindered amine compounds (C2-3):

(also referred to as HALS-C in the tables) [Adekastab, LA-77Y, NH type, produced by ADEKA Corporation]

Brominated flame retardant A:

bis(pentabromophenyl)ethane [Saytex 8010 produced by Albemarle Corporation]

Brominated flame retardant B:

2,4,6-tris(2,4,6-tribromophenoxy)-1,3,5-triazine [PYROGUARD SR245 produced by Dai-ichi Kogyo Seiyaku Co., Ltd.]

[Optional Additives]

(Phenolic Antioxidant)
3-(3,5-di-tert-butyl-4-hydroxyphenyl)propionic acid stearyl [Irganox 1076 produced by BASF]

(Phosphorus Antioxidant)
Tris(2,4-di-tert-butylphenyl)phosphite [Irgafos168 produced by BASF]

### Examples 1-24

After Irganox1076 and Irgafos168 were added in 0.2 mass parts each to 100 mass parts of the total of the components, (A1) component, and (B) components, as the composition ratios listed in Table 2-1 and Table 2-2, the mixture was pre-mixed. The obtained premixed material was mixed in batches, and then extruded using a twin screw extruder (TEM-26SS produced by Toshiba Machine Co., Ltd.) at a temperature range of 180° C. to 230° C. to produce pellets of a styrene-based resin composition as a kneaded material. At this time, a screw speed was 150 rpm and a discharge rate was 10 kg/hr. In Examples 10 to 12, 4-t-butyl catechol was added in pre-mixing with the (A1) component.

The pellets obtained in this manner were made into specimens (a) by molding using an injection molding machine produced by The Japan Steel Works, Ltd., equipped with a mold in dimensions of 127 mm×12.7 mm×thickness of 1.5 mm or pin gate flat mold of 1.5 mm, at a cylinder temperature of 220° C., a mold temperature of 50° C., an injection pressure (gauge pressure) of 40 MPA to 60 MPa, an injection speed (panel setting value) of 50%, and injection time/cooling time=5 sec/20 sec. Then, measurement of properties, evaluation of flammability, and the like were performed. The results are listed in Tables 2-1 and 2-2.

To further evaluate transmission loss and adhesion, the pellets of the styrene-based resin compositions of Examples 1 to 12 above were made into sheets of a thickness of 0.3 mm by press molding. Then, electrolytic copper foil (CF-T4X-SVR-12 produced by Fukuda Metal Foil & Powder Co., Ltd.) of a thickness of 12 μm was laminated on the sheets in the order of copper foil/sheet/copper foil, and then pressed at a temperature of 220° C. and a pressure of 1.3 MPa for 5 minutes to obtain flexible double-sided metal laminated plates. Then, the transmission loss and adhesion of the produced flexible double-sided metal laminated plates were evaluated. The results are listed in Tables 3 and 4.

### Comparative Examples 1-11

In Comparative Examples 1-11, pellets of resin compositions were obtained in the same manner as in the Examples except that the compositions were changed as listed in Table 3, and then specimens (a) were prepared. The results of the measurement and evaluation of individual physical properties are listed in Table 3. Note that, in Comparative Examples 2, 4, 6, 8, 9, 10, and 11, 4-t-butyl catechol was added in a predetermined amount in pre-mixing with the (A2) component.

TABLE 2

| | | | | Exam- | Exam- | Exam- | Exam- | Exam- | Exam- |
|---|---|---|---|---|---|---|---|---|---|
| | | | | ple 1 | ple 2 | ple 3 | ple 4 | ple 5 | ple 6 |
| Composition | (A1) component | GPPS-A | mass parts | 100 | | | 96 | | |
| of styrene | | HIPS-A | mass parts | | 100 | | | 96 | |
| resin | | Styrene copolymer (a) | mass parts | | | 100 | | | 96 |
| composition | | Styrene copolymer (b) | mass parts | | | | | | |
| | | (MMA 0%) | | | | | | | |
| | | Styrene copolymer (c) | mass parts | | | | | | |
| | | (MMA 15.2%) | | | | | | | |
| | | Styrene copolymer (d) | mass parts | | | | | | |
| | | (MAA 16.3%) | | | | | | | |
| | | Styrene copolymer (e) | mass parts | | | | | | |
| | | (divinylbenzene 6%) | | | | | | | |
| | (B) component | Phosphonic acid ester | mass parts | | | | 3 | 3 | 3 |
| | | compound | | | | | | | |
| | | Phosphate ester compound | mass parts | | | | | | |
| | | (Compound II-2) | | | | | | | |
| | | Bromine-based flame | mass parts | | | | | | |
| | | retardant A | | | | | | | |
| | | Bromine-based flame | mass parts | | | | | | |
| | | retardant B | | | | | | | |
| | | Phosphinic acid-A | mass parts | | | | | | |
| | | Phosphinic acid-B | mass parts | | | | | | |
| | | HALS-A | mass parts | | | | 1 | 1 | 1 |
| | | HALS-B | mass parts | | | | | | |
| | | HALS-C | mass parts | | | | | | |
| | Optional additive | Irganox1076 | mass parts | 0.2 | 0.2 | 0.2 | 0.2 | 0.2 | 0.2 |
| | component | Irgafos168 | mass parts | 0.2 | 0.2 | 0.2 | 0.2 | 0.2 | 0.2 |
| | 4-t-butylcatechol | | μg/g | 1.5 | 1.1 | 0.6 | 1.44 | 1.06 | 0.58 |
| | Content (μg) per gram of (A1) component | | | | | | | | |
| | Total amount of dimers and trimers | | μg/g | 4530 | 2840 | 3720 | 4350 | 2730 | 3570 |
| | Content (μg) per gram of (A1) component | | | | | | | | |
| Evaluation | Relative dielectric constant | | — | 2.3 | 2.3 | 2.5 | 2.4 | 2.4 | 2.6 |
| | Dielectric loss tangent | | — | 0.0005 | 0.0006 | 0.0021 | 0.0015 | 0.0012 | 0.0036 |
| | Dielectric loss tangent (80° C. 500 hours) | | kJ/m² | 0.0015 | 0.0015 | 0.0025 | 0.0022 | 0.0025 | 0.0042 |
| | Yellow index (YI) | | — | −6.5 | −14 | 0.2 | 0.3 | −3 | 3.4 |
| | ΔYI (80° C. 500 hours) | | — | 5.2 | 8.5 | 6.1 | 5.3 | 7.5 | 6 |
| | Flame retardance | | — | NOT V | NOT V | NOT V | V-2 | V-2 | V-2 |
| | Burning rate | | mm/min | 79 | 83 | 80 | 68 | 72 | 71 |
| | Heat resistance | | ° C. | 100 | 87 | 127 | 96 | 83 | 124 |
| | Minimum copper foil adhesion | | N/mm | 1.12 | 1.23 | 1.26 | 1.24 | 1.32 | 1.3 |
| | | | | Exam- | Exam- | Exam- | Exam- | Exam- | Exam- |
| | | | | ple 7 | ple 8 | ple 9 | ple 10 | ple 11 | ple 12 |
| Composition | (A1) component | GPPS-A | mass parts | 95 | | | 100 | 96 | |
| of styrene | | HIPS-A | mass parts | | 92 | 75 | | | 75 |
| resin | | Styrene copolymer (a) | mass parts | | | | | | |
| composition | | Styrene copolymer (b) | mass parts | | | | | | |
| | | (MMA 0%) | | | | | | | |
| | | Styrene copolymer (c) | mass parts | | | | | | |
| | | (MMA 15.2%) | | | | | | | |
| | | Styrene copolymer (d) | mass parts | | | | | | |
| | | (MAA 16.3%) | | | | | | | |
| | | Styrene copolymer (e) | mass parts | | | | | | |
| | | (divinylbenzene 6%) | | | | | | | |
| | (B) component | Phosphonic acid ester | mass parts | | | | | 3 | |
| | | compound | | | | | | | |
| | | Phosphate ester compound | mass parts | 4 | | | | | |
| | | (Compound II-2) | | | | | | | |
| | | Bromine-based flame | mass parts | | 8 | | | | |
| | | retardant A | | | | | | | |
| | | Bromine-based flame | mass parts | | | 25 | | | 25 |
| | | retardant B | | | | | | | |
| | | Phosphinic acid-A | mass parts | | | | | | |
| | | Phosphinic acid-B | mass parts | | | | | | |
| | | HALS-A | mass parts | 1 | | | | 1 | |
| | | HALS-B | mass parts | | | | | | |
| | | HALS-C | mass parts | | | | | | |
| | Optional additive | Irganox1076 | mass parts | 0.2 | 0.2 | 0.2 | 0.2 | 0.2 | 0.2 |
| | component | Irgafos168 | mass parts | 0.2 | 0.2 | 0.2 | 0.2 | 0.2 | 0.2 |
| | 4-t-butylcatechol | | μg/g | 1.43 | 1.01 | 0.83 | 5.5 | 5.44 | 4.01 |
| | Content (μg) per gram of (A1) component | | | | | | | | |
| | Total amount of dimers and trimers | | μg/g | 4300 | 2610 | 2130 | 4350 | 4350 | 2130 |
| | Content (μg) per gram of (A1) component | | | | | | | | |
| Evaluation | Relative dielectric constant | | — | 2.4 | 2.8 | 2.9 | 2.3 | 2.4 | 2.9 |
| | Dielectric loss tangent | | — | 0.0012 | 0.0063 | 0.012 | 0.0006 | 0.001 | 0.012 |
| | Dielectric loss tangent (80° C. 500 hours) | | kJ/m² | 0.0018 | 0.0098 | 0.016 | 0.0022 | 0.004 | 0.019 |
| | Yellow index (YI) | | — | −0.5 | 3.4 | 5.6 | 0.4 | 2.1 | 8.5 |
| | ΔYI (80° C. 500 hours) | | — | 5.7 | 8 | 10.4 | 10 | 7.6 | 15.6 |
| | Flame retardance | | — | V-2 | V-2 | V-0 | NOT V | V-2 | V-0 |
| | Burning rate | | mm/min | 66 | 73 | 50 | 79 | 69 | 50 |
| | Heat resistance | | ° C. | 93 | 86 | 88 | 99 | 96 | 87 |
| | Minimum copper foil adhesion | | N/mm | 1.1 | 1.15 | 1.1 | 1.05 | 1.2 | 1.02 |
| | | | | Exam- | Exam- | Exam- | Exam- | Exam- | Exam- |
| | | | | ple 13 | ple 14 | ple 15 | ple 16 | ple 17 | ple 18 |
| Composition | (A1) component | GPPS-A | mass parts | | | | | | |
| of styrene | | HIPS-A | mass parts | | | | | | |
| resin | | Styrene copolymer (a) | mass parts | | | | | | |
| composition | | Styrene copolymer (b) | mass parts | | | 100 | 96 | | |
| | | (MMA 0%) | | | | | | | |
| | | Styrene copolymer (c) | mass parts | | | | | 100 | 96 |
| | | (MMA 15.2%) | | | | | | | |
| | | Styrene copolymer (d) | mass parts | | | | | | |
| | | (MAA 16.3%) | | | | | | | |
| | | Styrene copolymer (e) | mass parts | 100 | 96 | | | | |
| | | (divinylbenzene 6%) | | | | | | | |
| | (B) component | Phosphonic acid ester | mass parts | | 3 | | 3 | | 3 |
| | | compound | | | | | | | |
| | | Phosphate ester compound | mass parts | | | | | | |
| | | (Compound II-2) | | | | | | | |
| | | Bromine-based flame | mass parts | | | | | | |
| | | retardant A | | | | | | | |
| | | Bromine-based flame | mass parts | | | | | | |
| | | retardant B | | | | | | | |
| | | Phosphinic acid-A | mass parts | | | | | | |
| | | Phosphinic acid-B | mass parts | | | | | | |
| | | HALS-A | mass parts | | 1 | | 1 | | 1 |
| | | HALS-B | mass parts | | | | | | |
| | | HALS-C | mass parts | | | | | | |
| | Optional additive | Irganox1076 | mass parts | 0.2 | 0.2 | 0.2 | 0.2 | 0.2 | 0.2 |
| | component | Irgafos168 | mass parts | 0.2 | 0.2 | 0.2 | 0.2 | 0.2 | 0.2 |

| | | | | | | | | |
|---|---|---|---|---|---|---|---|---|
| | 4-t-butylcatechol | μg/g | 1.4 | 1.34 | 0.7 | 0.67 | 0.6 | 0.58 |
| | Content (μg) per gram of (A1) component | | | | | | | |
| | Total amount of dimers and trimers | μg/g | 4720 | 4530 | 3850 | 3700 | 3410 | 3270 |
| | Content (μg) per gram of (A1) component | | | | | | | |
| Evaluation | Relative dielectric constant | — | 2.3 | 2.3 | 2.4 | 2.4 | 2.6 | 2.7 |
| | Dielectric loss tangent | — | 0.0005 | 0.0008 | 0.0016 | 0.0024 | 0.0032 | 0.0047 |
| | Dielectric loss tangent (80° C. 500 hours) | kJ/m² | 0.0075 | 0.009 | 0.0021 | 0.003 | 0.0038 | 0.0055 |
| | Yellow index (YI) | — | 1.2 | 8.5 | 0.1 | 2.7 | 0.4 | 4 |
| | ΔYI (80° C. 500 hours) | — | 15 | 17 | 5.3 | 5.3 | 7.6 | 8 |
| | Flame retardance | — | NOT V | V-2 | NOT V | V-2 | NOT V | NOT V |
| | Burning rate | mm/min | 80 | 72 | 79 | 70 | 82 | 80 |
| | Heat resistance | ° C. | 99 | 95 | 118 | 115 | 132 | 128 |
| | Minimum copper foil adhesion | N/mm | 1 | 1.03 | 1.28 | 1.34 | 1.1 | 1.13 |

| | | | | Exam- | Exam- | Exam- | Exam- | Exam- | Exam- |
|---|---|---|---|---|---|---|---|---|---|
| | | | | ple 19 | ple 20 | ple 21 | ple 22 | ple 23 | ple 24 |
| Composition | (A1) component | GPPS-A | mass parts | | | 96 | 96 | 96 | 96 |
| of styrene | | HIPS-A | mass parts | | | | | | |
| resin | | Styrene copolymer (a) | mass parts | | | | | | |
| composition | | Styrene copolymer (b) | mass parts | | | | | | |
| | | (MMA 0%) | | | | | | | |
| | | Styrene copolymer (c) | mass parts | | | | | | |
| | | (MMA 15.2%) | | | | | | | |
| | | Styrene copolymer (d) | mass parts | 100 | 96 | | | | |
| | | (MAA 16.3%) | | | | | | | |
| | | Styrene copolymer (e) | mass parts | | | | | | |
| | | (divinylbenzene 6%) | | | | | | | |
| | (B) component | Phosphonic acid ester | mass parts | | 3 | | | | |
| | | compound | | | | | | | |
| | | Phosphate ester compound | mass parts | | | | | | |
| | | (Compound II-2) | | | | | | | |
| | | Bromine-based flame | mass parts | | | | | | |
| | | retardant A | | | | | | | |
| | | Bromine-based flame | mass parts | | | | | | |
| | | retardant B | | | | | | | |
| | | Phosphinic acid-A | mass parts | | | 3 | | 3 | 3 |
| | | Phosphinic acid-B | mass parts | | | | 3 | | |
| | | HALS-A | mass parts | | 1 | 1 | 1 | | |
| | | HALS-B | mass parts | | | | | 1 | |
| | | HALS-C | mass parts | | | | | | 1 |
| | Optional additive | Irganox1076 | mass parts | 0.2 | 0.2 | 0.2 | 0.2 | 0.2 | 0.2 |
| | component | Irgafos168 | mass parts | 0.2 | 0.2 | 0.2 | 0.2 | 0.2 | 0.2 |

| | | | | | | | | |
|---|---|---|---|---|---|---|---|---|
| | 4-t-butylcatechol | μg/g | 0.6 | 0.58 | 1.44 | 1.44 | 1.44 | 1.44 |
| | Content (μg) per gram of (A1) component | | | | | | | |
| | Total amount of dimers and trimers | μg/g | 3460 | 3600 | 4350 | 4350 | 4350 | 4350 |
| | Content (μg) per gram of (A1) component | | | | | | | |
| Evaluation | Relative dielectric constant | — | 2.5 | 2.6 | 2.4 | 2.4 | 2.4 | 2.4 |
| | Dielectric loss tangent | — | 0.0022 | 0.0029 | 0.0009 | 0.0014 | 0.001 | 0.001 |
| | Dielectric loss tangent (80° C. 500 hours) | kJ/m² | 0.0027 | 0.0037 | 0.0015 | 0.002 | 0.0017 | 0.0025 |
| | Yellow index (YI) | — | 0.3 | 3 | −4.5 | 0.5 | −5.1 | −4.6 |
| | ΔYI (80° C. 500 hours) | — | 5.9 | 5.5 | 2.2 | 5.5 | 1.8 | 3.2 |
| | Flame retardance | — | NOT V | NOT V | V-2 | V-2 | V-2 | V-2 |
| | Burning rate | mm/min | 81 | 79 | 70 | 75 | 68 | 87 |
| | Heat resistance | ° C. | 130 | 127 | 98 | 97 | 96 | 98 |
| | Minimum copper foil adhesion | N/mm | 1.12 | 1.1 | 1.28 | 1.2 | 1.26 | 1.26 |

TABLE 3

| | | | | Compar- | Compar- | Compar- | Compar- | Compar- | Compar- |
|---|---|---|---|---|---|---|---|---|---|
| | | | | ative | ative | ative | ative | ative | ative |
| | | | | Example 1 | Example 2 | Example 3 | Example 4 | Example 5 | Example 6 |
| Composition | (A1) component | GPPS-A | mass parts | | 100 | | | | 96 |
| of styrene | | GPPS-B | mass parts | 100 | | | | 96 | |
| resin | | HIPS-A | mass parts | | | | 100 | | |
| composition | | HIPS-B | mass parts | | | 100 | | | |
| | (B) component | Phosphonic acid ester | mass parts | | | | | 3 | 3 |
| | | compound | | | | | | | |
| | | Phosphate ester compound | mass parts | | | | | | |
| | | (Compound II-2) | | | | | | | |
| | | Bromine-based flame | mass parts | | | | | | |
| | | retardant A | | | | | | | |
| | | Bromine-based flame | mass parts | | | | | | |
| | | retardant B | | | | | | | |
| | | HALS-A | mass parts | | | | | 1 | 1 |
| | Optional additive | Irganox1076 | mass parts | 0.2 | 0.2 | 0.2 | 0.2 | 0.2 | 0.2 |
| | component | Irgafos168 | mass parts | 0.2 | 0.2 | 0.2 | 0.2 | 0.2 | 0.2 |

| | | | | | | | | |
|---|---|---|---|---|---|---|---|---|
| | 4-t-butylcatechol | μg/g | 1.8 | 6.5 | 1.7 | 6.7 | 1.73 | 6.44 |
| | Content (μg) per gram of (A1) component | | | | | | | |
| | Total amount of dimers and trimers | μg/g | 5880 | 4530 | 5380 | 5380 | 5640 | 4350 |
| | Content (μg) per gram of (A1) component | | | | | | | |
| Evaluation | Relative dielectric constant | — | 2.4 | 2.3 | 2.4 | 2.3 | 2.5 | 2.4 |
| | Dielectric loss tangent | — | 0.0011 | 0.0012 | 0.0009 | 0.0016 | 0.0018 | 0.0028 |
| | Dielectric loss tangent (80° C. 500 hours) | kJ/m² | 0.0055 | 0.013 | 0.0034 | 0.017 | 0.016 | 0.023 |
| | Yellow index (YI) | — | −3.5 | −1.5 | −11 | −8.4 | 2.3 | 4.2 |
| | ΔYI (80° C. 500 hours) | — | 6.3 | 12.5 | 10.2 | 16.8 | 7.2 | 16.3 |
| | Flame retardance | — | NOT V | NOT V | NOT V | NOT V | NOT V | NOT V |
| | Burning rate | mm/min | 82 | 81 | 84 | 84 | 72 | 70 |
| | Heat resistance | ° C. | 99 | 99 | 87 | 86 | 96 | 95 |
| | Minimum copper foil adhesion | N/mm | 1.1 | 1.08 | 1.12 | 1.11 | 1.15 | 1.16 |

| | | | | Compar- | Compar- | Compar- | Compar- | Compar- |
|---|---|---|---|---|---|---|---|---|
| | | | | ative | ative | ative | ative | ative |
| | | | | Example 7 | Example 8 | Example 9 | Example 10 | Example 11 |
| Composition | (A1) component | GPPS-A | mass parts | | | 95 | | |
| of styrene | | GPPS-B | mass parts | | | | | |
| resin | | HIPS-A | mass parts | | 96 | | | |
| composition | | HIPS-B | mass parts | 96 | | | 92 | 75 |
| | (B) component | Phosphonic acid ester | mass parts | 3 | 3 | | | |
| | | compound | | | | | | |
| | | Phosphate ester compound | mass parts | | | 4 | | |
| | | (Compound II-2) | | | | | | |
| | | Bromine-based flame | mass parts | | | | 8 | |
| | | retardant A | | | | | | |
| | | Bromine-based flame | mass parts | | | | | 25 |
| | | retardant B | | | | | | |
| | | HALS-A | mass parts | 1 | 1 | 1 | | |
| | Optional additive | Irganox1076 | mass parts | 0.2 | 0.2 | 0.2 | 0.2 | 0.2 |
| | component | Irgafos168 | mass parts | 0.2 | 0.2 | 0.2 | 0.2 | 0.2 |

| | | | | | | | |
|---|---|---|---|---|---|---|---|
| | 4-t-butylcatechol | μg/g | 1.06 | 6.06 | 6.43 | 6.56 | 6.28 |
| | Content (μg) per gram of (A1) component | | | | | | |
| | Total amount of dimers and trimers | μg/g | 5160 | 2730 | 4300 | 4950 | 4040 |
| | Content (μg) per gram of (A1) component | | | | | | |
| Evaluation | Relative dielectric constant | — | 2.5 | 2.4 | 2.4 | 2.8 | 2.9 |
| | Dielectric loss tangent | — | 0.0016 | 0.0023 | 0.0022 | 0.0075 | 0.014 |
| | Dielectric loss tangent (80° C. 500 hours) | kJ/m² | 0.022 | 0.028 | 0.017 | 0.038 | 0.052 |
| | Yellow index (YI) | — | −2 | 1.2 | 3.2 | 7.4 | 10.7 |
| | ΔYI (80° C. 500 hours) | — | 12.4 | 20.4 | 12.9 | 21 | 23.3 |
| | Flame retardance | — | NOT V | NOT V | NOT V | V-2 | V-2 |
| | Burning rate | mm/min | 75 | 74 | 71 | 75 | 53 |
| | Heat resistance | ° C. | 83 | 84 | 93 | 86 | 87 |
| | Minimum copper foil adhesion | N/mm | 1.18 | 1.18 | 1.02 | 1.02 | 0.96 |

It can be seen from Tables 2-1 and 2-2 that Examples 1 to 24 have excellent dielectric constant, dielectric loss tangent and variation thereof, and color tone. Even after exposure to an oven, which is assumed to be usage environment, there is little variation in the dielectric loss tangent and color tone. Furthermore, addition of the flame retardant allows to obtain flame retardant materials with excellent dielectric properties and color tone.

As listed in Table 3, when the amount of 4-t-butylcatechol or dimers and trimers is more than a predetermined amount, the dielectric loss tangent and variation thereof and variation in the color tone after exposure to the oven, which is assumed to be the usage environment, become larger. In addition, when the flame retardant is used in combination, the flame retardance is reduced.

TABLE 4

| | Exam- | Exam- | Exam- | Exam- | Exam- | Exam- | Exam- | Exam- | Exam- | Exam- | Exam- | Exam- |
|---|---|---|---|---|---|---|---|---|---|---|---|---|
| | ple 1 | ple 2 | ple 3 | ple 4 | ple 5 | ple 6 | ple 7 | ple 8 | ple 9 | ple 10 | ple 11 | ple 12 |
| Adhesion | 1 | 1 | 0 | 0 | 0 | 0 | 2 | 1 | 1 | 2 | 1 | 2 |
| Transmission loss (sample (A): | 0.18 | 0.18 | 0.21 | 0.2 | 0.22 | 0.25 | 0.2 | 0.31 | 0.37 | 0.18 | 0.19 | 0.37 |
| initial) dB/mm | | | | | | | | | | | | |
| Transmission loss (sample (B): | 0.2 | 0.2 | 0.23 | 0.22 | 0.23 | 0.27 | 0.21 | 0.33 | 0.4 | 0.21 | 0.25 | 0.43 |
| after load) dB/mm | | | | | | | | | | | | |

TABLE 5

| | Compar- | Compar- | Compar- | Compar- | Compar- | Compar- | Compar- | Compar- | Compar- | Compar- | Compar- |
|---|---|---|---|---|---|---|---|---|---|---|---|
| | ative | ative | ative | ative | ative | ative | ative | ative | ative | ative | ative |
| | Exam- | Exam- | Exam- | Exam- | Exam- | Exam- | Exam- | Exam- | Exam- | Exam- | Exam- |
| | ple 1 | ple 2 | ple 3 | ple 4 | ple 5 | ple 6 | ple 7 | ple 8 | ple 9 | ple 10 | ple 11 |
| Adhesion | 4 | 1 | 3 | 3 | 4 | 1 | 3 | 2 | 2 | 2 | 2 |
| Transmission loss | 0.21 | 0.2 | 0.2 | 0.21 | 0.23 | 0.25 | 0.22 | 0.23 | 0.23 | 0.32 | 0.39 |
| (sample (A): | | | | | | | | | | | |
| initial) dB/mm | | | | | | | | | | | |
| Transmission loss | 0.28 | 0.38 | 0.27 | 0.41 | 0.43 | 0.57 | 0.57 | 0.6 | 0.44 | 0.88 | 1.21 |
| (sample (B): after | | | | | | | | | | | |
| load) dB/mm | | | | | | | | | | | |

It can be seen from Tables 2-1, 2-2, and 4 that the patch antennas made of the styrene-based resin compositions of Examples 1 to 12 have excellent adhesion to the substrates, dielectric constant, dielectric loss tangent, and color tone. Even after exposure to an oven, which is assumed to be the usage environment, there is little variation in the dielectric loss tangent and color tone, and there is little decrease in the transmission loss. Furthermore, the addition of a flame retardant allows to obtain flame retardant materials with excellent dielectric properties and color tone. On the other hand, as listed in Table 5, when the amount of 4-t-butyl catechol or dimers and trimers is more than a predetermined amount, the dielectric loss tangent and color tone vary largely, and the transmission loss decreases largely after exposure to the oven, which is assumed to be the usage environment. In addition, when the flame retardant is used in combination, the flame retardance is reduced.

In addition, since Examples 1-12 all use the styrene-based resins, the impact resistance is superior to that of glass dielectrics.

### Examples 25 to 33

After Irganox1076 and Irgafos168 were added in 0.2 mass parts each to 100 mass parts of the components, (A1) component, and (B) components in the composition ratios listed in Table 6, the mixture was pre-mixed. The obtained premixed material was mixed in batches, and then extruded (screw speed of 150 rpm and discharge rate of 10 kg/hr) using a twin screw extruder (TEM-26SS produced by Toshiba Machine Co., Ltd.) at a temperature range of 180° C. to 230° C. to produce pellets of frame-retardant styrene-based resin compositions. The pellets of the frame-retardant styrene-based resin compositions obtained in this manner were made into specimens (a) by molding using an injection molding machine produced by The Japan Steel Works, Ltd., equipped with a ISO527-2 multi-purpose test piece type 1A, at a cylinder temperature of 220° C., a mold temperature of 50° C., an injection pressure (gauge pressure) of 40 MPA to 60 MPa, an injection speed (panel setting value) of 50%, and injection time/cooling time=5 sec/20 sec, and physical properties were measured. Also, specimens (b) were produced using a double-ended gate flat mold in dimensions of 127 mm×12.7 mm×thickness of 0.8 mm and in the same conditions as those of the specimens (a), and flame retardance was measured. The results are listed in Table 6. In addition, the results of the first burning time (seconds) for the first set of UL94-V test on Examples 25 to 33 are listed in Table 7.

TABLE 6

| | | | | Exam- | Exam- | Exam- | Exam- | Exam- | Exam- | Exam- | Exam- | Exam- |
|---|---|---|---|---|---|---|---|---|---|---|---|---|
| | | | | ple 25 | ple 26 | ple 27 | ple 28 | ple 29 | ple 30 | ple 31 | ple 32 | ple 33 |
| Composition | (A2) | HIPS | mass parts | 94.5 | | | | | | | | |
| | component | GPPS | mass parts | | 94.5 | | 97.8 | 86.0 | | 94.5 | 94.5 | 86.0 |
| | | Styrene copolymer (a) | mass parts | | | 94.5 | | | 70.0 | | | |
| | (C1) | Phosphinic acid-A | mass parts | 5.0 | 5.0 | 5.0 | 2.0 | 12.0 | 18.0 | | 5.0 | 12.0 |
| | component | Phosphinic acid-B | mass parts | | | | | | | 5.0 | | |
| | Phosphonic acid ester compound | | mass parts | | | | | | | | | |
| | (C2) | HALS-A | mass parts | 0.5 | 0.5 | 0.5 | | | | 0.5 | | |
| | component | HALS-B | mass parts | | | | 0.2 | 2.0 | 3.0 | | | |
| | | HALS-C | mass parts | | | | | | | | 0.5 | 2.0 |
| | Antioxidant | Irganox1076 | mass parts | 0.2 | 0.2 | 0.2 | 0.2 | 0.2 | 0.2 | 0.2 | 0.2 | 0.2 |
| | | Irgafos 168 | mass parts | 0.2 | 0.2 | 0.2 | 0.2 | 0.2 | 0.2 | 0.2 | 0.2 | 0.2 |

| | | | | | | | | | | | |
|---|---|---|---|---|---|---|---|---|---|---|---|
| Evaluation | flame retardance (thickness | Grade | V-2 | V-2 | V-2 | V-2 | V-0 | V-0 | V-2 | V-2 | V-2 |
| | 0.8 mm) | Average | 1.84 | 1.2 | 2.48 | 3.28 | 0.72 | 0.4 | 3.04 | 3.76 | 3.84 |
| | | deviation | | | | | | | | | |
| | Burning rate (thickness 0.8 mm) | mm/min | 70 | 68 | 72 | 76 | 60 | 54 | 75 | 82 | 71 |
| | Vicat softening point | ° C. | 88 | 96 | 116 | 99 | 89 | 104 | 94 | 95 | 90 |

| Yellow index | | −8.1 | 0.4 | 2.1 | 0.2 | 2.4 | 4.8 | 4.2 | 1.7 | 2.2 |
|---|---|---|---|---|---|---|---|---|---|---|
| Molding | Silver streaks | Good | Good | Good | Good | Good | Good | Good | Good | Good |
| appearance | Fogging | Good | Good | Good | Good | Good | Good | Good | Good | Good |

TABLE 7

| Number of burning | Example 25 | Example 26 | Example 27 | Example 28 | Example 29 | Example 30 | Example 31 | Example 32 | Example 33 |
|---|---|---|---|---|---|---|---|---|---|
| 1st set (seconds) | 12 | 3 | 11 | 17 | 1 | 1 | 8 | 12 | 8 |
| 2nd set (seconds) | 8 | 5 | 8 | 11 | 0 | 1 | 12 | 15 | 6 |
| 3rd set (seconds) | 7 | 2 | 5 | 8 | 3 | 0 | 16 | 18 | 7 |
| 4th set (seconds) | 10 | 6 | 12 | 10 | 1 | 2 | 9 | 5 | 12 |
| 5th set (seconds) | 12 | 4 | 12 | 16 | 1 | 1 | 6 | 16 | 18 |
| Average deviation | 1.84 | 1.25 | 2.48 | 3.28 | 0.72 | 0.4 | 3.04 | 3.76 | 3.84 |

### Comparative Examples 12-20

Comparative Examples 12-20 were conducted in the same manner as Example 25, except that the compositions were changed as listed in Table 8. The results of the measurement and evaluation of each physical property are listed in Table 8. In addition, the results of the evaluation of the first burning time (seconds) for each set of UL94-V test on Comparative Examples 12-20 are listed in Table 9.

TABLE 8

| | | | | Comparative | Comparative | Comparative | Comparative | Comparative |
|---|---|---|---|---|---|---|---|---|
| | | | | Example 12 | Example 13 | Example 14 | Example 15 | Example 16 |
| Composition | (A2) component | HIPS | mass parts | 95.0 | | | 99.5 | |
| | | GPPS | mass parts | | 95.0 | | | 99.5 |
| | | Styrene copolymer (a) | mass parts | | | 95.0 | | |
| | (C1) component | Phosphinic acid-A | mass parts | 5.0 | 5.0 | 5.0 | | |
| | | Phosphinic acid-B | mass parts | | | | | |
| | Phosphonic acid ester compound | | mass parts | | | | | |
| | (C2) component | HALS-A | mass parts | | | | 0.5 | 0.5 |
| | | HALS-B | mass parts | | | | | |
| | | HALS-C | mass parts | | | | | |
| | Antioxidant | Irganox1076 | mass parts | 0.2 | 0.2 | 0.2 | 0.2 | 0.2 |
| | | Irgafos 168 | mass parts | 0.2 | 0.2 | 0.2 | 0.2 | 0.2 |

| | | | | | | | |
|---|---|---|---|---|---|---|---|
| Evaluation | flame retardance (thickness 0.8 mm) | Grade | NOT V | NOT V | NOT V | NOT V | NOT V |
| | | Average | 11.12 | 8.8 | 10.64 | 7.84 | 8.08 |
| | | deviation | | | | | |
| | Burning rate (thickness 0.8 mm) | mm/min | 87 | 85 | 89 | 102 | 95 |
| | Vicat softening point | ° C. | 90 | 98 | 119 | 90 | 98 |

| Yellow index | | −8.3 | 0.2 | 1.7 | 1.4 | 5.4 |
|---|---|---|---|---|---|---|
| Molding | Silver streaks | Poor | Poor | Poor | Good | Good |
| appearance | Fogging | Poor | Poor | Poor | Good | Good |

| | | | | Comparative | Comparative | Comparative | Comparative |
|---|---|---|---|---|---|---|---|
| | | | | Example 17 | Example 18 | Example 19 | Example 20 |
| Composition | (A2) component | HIPS | mass parts | | | | |
| | | GPPS | mass parts | | | 78.5 | 94.5 |
| | | Styrene copolymer (a) | mass parts | 99.5 | 76.0 | | |
| | (C1) component | Phosphinic acid-A | mass parts | | 21.0 | 18.0 | |
| | | Phosphinic acid-B | mass parts | | | | |

| Phosphonic acid ester compound | | mass parts | | | | 5.0 |
|---|---|---|---|---|---|---|
| (C2) component | HALS-A | mass parts | 0.5 | 3.0 | 3.5 | 0.5 |
| | HALS-B | mass parts | | | | |
| | HALS-C | mass parts | | | | |
| Antioxidant | Irganox1076 | mass parts | 0.2 | 0.2 | 0.2 | 0.2 |
| | Irgafos 168 | mass parts | 0.2 | 0.2 | 0.2 | 0.2 |

| | | | | | | |
|---|---|---|---|---|---|---|
| Evaluation | flame retardance (thickness 0.8 mm) | Grade | NOT V | V-0 | V-0 | V-2 |
| | | Average | 7.36 | 0.48 | 0.32 | 1.76 |
| | | deviation | | | | |
| | Burning rate (thickness 0.8 mm) | mm/min | 104 | 53 | 53 | 74 |
| | Vicat softening point | ° C. | 118 | 85 | 100 | 92 |

| Yellow index | | 7.7 | 2.2 | 5.9 | 5.3 |
|---|---|---|---|---|---|
| Molding | Silver streaks | Good | Good | Good | Poor |
| appearance | Fogging | good | Poor | Good | Poor |

TABLE 9

| | Comparative | Comparative | Comparative | Comparative | Comparative | Comparative | Comparative | Comparative | Comparative |
|---|---|---|---|---|---|---|---|---|---|
| Number of burning | Example 12 | Example 13 | Example 14 | Example 15 | Example 16 | Example 17 | Example 18 | Example 19 | Example 20 |
| 1st set (seconds) | 34 | 2 | 40 | 40 | 36 | 48 | 0 | 2 | 5 |
| 2nd set (seconds) | 8 | 28 | 5 | 43 | 32 | 44 | 1 | 1 | 12 |
| 3rd set (seconds) | 7 | 18 | 33 | 20 | 38 | 28 | 1 | 1 | 8 |
| 4th set (seconds) | 25 | 8 | 25 | 26 | 13 | 34 | 1 | 1 | 7 |
| 5th set (seconds) | 33 | 24 | 16 | 35 | 24 | 30 | 0 | 1 | 7 |
| Average deviation | 11.1 | 8.8 | 10.6 | 7.8 | 8.1 | 7.4 | 0.5 | 0.3 | 1.8 |

Examples 25-33 have high flame resistance and excellent heat resistance, color tone, and molded appearance, as listed in Table 6 above. In particular, for the hindered amine compound (C2), the NOR-type hindered amine compound (C2) has a synergistic effect with the phosphinic acid compound (C1) in flame retardance. When the phosphinic acid compound (C1) is 9,10-dihydro-9-oxa-10-phosphaphenanthrene-10-oxide, the yellow index is lower and the color tone is better.

On the other hand, for Comparative Examples 12 to 15, as listed in Table 8, high flame retardance is not obtained without the addition of the hindered amine compound (C2), and the appearance of molded products, such as silver streaks and fogging, deteriorates. For Comparative Examples 16 to 17, as listed in Table 8, high flame retardance is not obtained without the addition of the phosphinic acid compound (C1), and the yellow index is high and there is no improvement in color tone. For Comparative Examples 18 and 19, as listed in Table 8, a large amount of the phosphinic acid compound (C1) decreases heat resistance and also decreases molded appearance. For Comparative Example 20, as listed in Table 8, there is no improvement in color tone and molded appearance with phosphonic acid ester. Also, as listed in Tables 7 and 9, when the average deviations of the burning time (seconds) for Examples 25 to 33 are compared with those of Comparative Examples 12 to 20, it is confirmed that variations in flame retardant effects are improved by using the frame-retardant styrene-based resin compositions of the Examples.

### INDUSTRIAL APPLICABILITY

The styrene-based resin compositions of the present disclosure, and molded products or patch antennas containing the compositions are effective as components of devices that communicate by electromagnetic waves having a frequency of 0.3 GHz to 300 GHz. Therefore, the present disclosure can be suitably used in housings or housing components, i.e. components of transmitting and receiving devices, cellular phones, tablets, laptops, navigation devices, surveillance cameras, photographic cameras, sensors, diving computers, audio units, remote controls, speakers, headphones, radios, televisions, lighting devices, home appliances, kitchen appliances, door or gate openers, operating devices for vehicle central locks, keys for keyless cars, temperature measurement or temperature display devices, measuring and control devices, and the like.

### REFERENCE SIGNS LIST

1 Patch antenna
2 Patch substrate
3 Dielectric layer
4 Ground substrate
5 Microstrip line
6 Power supply point
7 Through hole
W Width
L Length
h Thickness of dielectric layer
t Thickness of microstrip line

1. A styrene-based resin composition containing a styrene-based resin (A1) having styrene-based monomer units as repeating units, the styrene-based resin composition comprising:
6 μg or less of a catechol derivative contained in the styrene-based resin (A1) per gram of the styrene-based resin (A1), and a total amount of dimers of the styrene-based monomer units and trimers of the styrene-based monomer units contained in the styrene-based resin (A1) being 5000 μg or less per gram of the styrene-based resin (A1),
wherein the styrene-based resin composition has a dielectric constant of 3 or less and a dielectric loss tangent of 0.02 or less.

2. The styrene-based resin composition according to claim 1, wherein the styrene-based resin (A1) is a rubber-modified styrene-based resin in which particles of a rubbery polymer (a) are dispersed in a polymer matrix having monovinylstyrene-based monomer units as repeating units, or a styrene copolymer resin containing the styrene-based monomer units and unsaturated carboxylic acid monomer units and/or unsaturated carboxylic acid ester monomer units.

3. The styrene-based resin composition according to claim 1, further comprising a flame retardant (B).

4. The styrene-based resin composition according to claim 3, wherein the flame retardant (B) is one or two or more selected from a group consisting of phosphorus-based flame retardants, bromine-based flame retardants, and hindered amine compounds (C2).

5. The styrene-based resin composition according to claim 3, further comprising:
77.0 mass % to 98.8 mass % of the styrene-based resin (A1); and
1.0 mass % to 20.0 mass % of a phosphinic acid compound (C1) and a 0.2 mass % to 3.0 mass % of a hindered amine compound (C2), as the flame retardant (B).

6. The styrene-based resin composition according to claim 1, wherein the styrene-based resin (A1) is a thermoplastic styrene-based resin (b).

7. A styrene-based resin molded body comprising the styrene-based resin composition according to claim 1,
wherein the styrene-based resin molded body is for a component of an apparatus communicating by an electromagnetic wave with a frequency of 0.3 GHz to 300 GHz, or for a housing or a housing component.

8. The styrene-based resin molded body according to claim 7, wherein the styrene-based resin molded body is at least one selected from a group consisting of transmitters and receivers, cellular phones, tablets, laptops, navigation devices, surveillance cameras, photographic cameras, sensors, diving computers, audio units, remote controls, speakers, headphones, radios, televisions, lighting equipment, household appliances, kitchen appliances, door openers or gate openers, operating devices for vehicle central locking, keys for keyless cars, temperature measurement or temperature display devices, components of measurement and control devices, and housings or housing components.

9. A patch antenna comprising:
a patch substrate;
a ground substrate provided at a distance from the patch substrate; and
a dielectric layer sandwiched between the patch substrate and the ground substrate,
wherein
the dielectric layer is composed of a styrene-based resin composition containing a catechol derivative, a styrene-based resin (A1) having styrene-based monomer units as repeating units, dimers of the styrene-based monomer units, and trimers of the styrene-based monomer units,
the catechol derivative is 6 μg or less per gram of the styrene-based resin (A1), and
a total amount of the dimers of the styrene-based monomer units and the trimers of the styrene-based monomer units is 5000 μg or less per gram of the styrene-based resin (A1).
